(19) United States
(12) Patent Application Publication
(10) Pub. No.: US 2017/0373210 A1
(43) Pub. Date: Dec. 28, 2017

(54) SOLAR CELL MODULE

(71) Applicant: Panasonic Intellectual Property Management Co., Ltd., Osaka (JP)

(72) Inventors: Shoji SATO, Osaka (JP); Haruhisa HASHIMOTO, Osaka (JP)

(21) Appl. No.: 15/699,335

(22) Filed: Sep. 8, 2017

Related U.S. Application Data
(63) Continuation of application No. PCT/JP2016/000752, filed on Feb. 15, 2016.

(30) Foreign Application Priority Data
Mar. 31, 2015 (JP) 2015-072100

(51) Int. Cl. H01L 31/05; H01L 31/0224

(52) U.S. Cl. CPC H01L 31/0504; H01L 31/022425

(57) ABSTRACT

A solar cell module includes: two solar cells adjacent to each other in a direction parallel to a light-receiving surface; a tab line which is disposed on a front surface of one of the two solar cells and a back surface of the other of the two solar cells, and electrically connects the two solar cells; and bonding members which bond the tab line to the two solar cells, wherein bonding strength between the tab line and at least one of the two solar cells in an edge area on a side electrically connected with the other of the two solar cells by the tab line is lower than bonding strength between the tab line and the at least one of the two solar cells in a central area.

### CROSS REFERENCE TO RELATED APPLICATIONS

This application is a U.S. continuation application of PCT International Patent Application Number PCT/JP2016/000752 filed on Feb. 15, 2016, claiming the benefit of priority of Japanese Patent Application Number 2015-072100 filed on Mar. 31, 2015, the entire contents of which are hereby incorporated by reference.

### BACKGROUND

### 1. Technical Field

The present disclosure relates to a solar cell module.

### 2. Description of the Related Art

In recent years, solar cell modules have been progressively developed as photoelectric conversion devices which convert light energy into electric energy. Solar cell modules can directly convert inexhaustible sunlight into electricity, which has less environmental impact than power generation using fossil fuels. Accordingly, such solar cell modules generate power cleanly, and thus are expected to provide new energy sources.

For example, a solar cell module has a structure in which solar cells are sealed by a filler, between a front surface shield and a back surface shield. In the solar cell module, the solar cells are disposed in a matrix. Each pair of adjacent solar cells among solar cells linearly aligned in either the row direction or the column direction are connected by a tab line to form a string.

Japanese Unexamined Patent Application Publication No. 2008-135654 proposes a solar cell module in which a connection layer made of resin containing electrically conductive particles is disposed between a tab line which connects two solar cells and a bus bar electrode formed on the surface of a solar cell.

### SUMMARY

However, in a conventional solar cell module, stress may be applied to a tab line between solar cells due to expansion and contraction of the solar cells and the tab line that are caused by temperature cycling.

In view of this, the present disclosure has been conceived in order to address the above problem, and an object thereof is to provide a solar cell module which can reduce stress applied to a tab line.

In order to address the above problem, a solar cell module according to the present disclosure includes: two solar cells adjacent to each other in a direction parallel to a light-receiving surface of the solar cell module; a tab line which is disposed on a front surface of a first solar cell among the two solar cells and a back surface of a second solar cell among the two solar cells, and electrically connects the two solar cells; and bonding members which bond the tab line to the two solar cells, wherein bonding strength between the tab line and at least one of the two solar cells in a first edge area on a side electrically connected with the other of the two solar cells by the tab line is lower than bonding strength between the tab line and the at least one of the two solar cells in a central area.

The solar cell module according to the present disclosure reduces stress applied to a tab line.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a schematic plan view of a solar cell module according to Embodiment 1;

FIG. 2 is a plan view of a solar cell according to Embodiment 1;

FIG. 3 is a cross-sectional view illustrating a stack structure of the solar cell according to Embodiment 1;

FIG. 4 is a cross-sectional view of a structure of the solar cell module according to Embodiment 1 in the column direction;

FIG. 5A is a structural cross-sectional view illustrating a flow of electric charges from received light in the solar cell according to Embodiment 1;

FIG. 5B is a structural cross-sectional view illustrating a flow of electric charges from received light in a conventional solar cell;

FIG. 6 shows plan views illustrating an electrode configuration of the solar cell according to Embodiment 1 on a front surface side and a back surface side;

FIG. 7 shows plan views illustrating an electrode configuration of a solar cell according to Variation 1 of Embodiment 1 on a front surface side and a back surface side;

FIG. 8 shows plan views illustrating an electrode configuration of a solar cell according to Variation 2 of Embodiment 1 on a front surface side and a back surface side;

FIG. 9 shows plan views illustrating an electrode configuration of a solar cell according to Variation 3 of Embodiment 1 on a front surface side and a back surface side;

FIG. 10 is an explanatory diagram of effects of resistance loss depending on the electrode configuration according to Embodiment 1;

FIG. 11 shows plan views and a cross-sectional view illustrating an electrode configuration of a solar cell according to Embodiment 2;

FIG. 12 shows a plan view and a cross-sectional view illustrating an electrode configuration of a solar cell according to Variation 1 of Embodiment 2;

FIG. 13 shows plan views illustrating an electrode configuration of a solar cell according to Variation 2 of Embodiment 2 on a front surface side and a back surface side;

FIG. 14 shows plan views illustrating an electrode configuration of a solar cell according to Variation 3 of Embodiment 2 on a front surface side and a back surface side;

FIG. 15 shows plan views illustrating an electrode configuration of a solar cell according to Variation 4 of Embodiment 2 on a front surface side and a back surface side;

FIG. 16 shows plan views illustrating an electrode configuration of a solar cell according to Variation 5 of Embodiment 2 on a front surface side and a back surface side;

FIG. 17 shows plan views illustrating an electrode configuration of a solar cell according to Variation 6 of Embodiment 2 on a front surface side and a back surface side;

FIG. 18 shows plan views illustrating an electrode configuration of a solar cell according to Variation 7 of Embodiment 2 on a front surface side and a back surface side;

FIG. 19 shows plan views illustrating an electrode configuration of a solar cell according to Variation 8 of Embodiment 2 on a front surface side and a back surface side;

FIG. 20 shows plan views illustrating an electrode configuration of a solar cell according to Variation 9 of Embodiment 2 on a front surface side and a back surface side;

FIG. 21 shows plan views illustrating an electrode configuration of a solar cell according to Variation 10 of Embodiment 2 on a front surface side and a back surface side;

FIG. 22A is a plan view illustrating an electrode configuration of a solar cell according to Variation 11 of Embodiment 2; and

FIG. 22B is a plan view illustrating an electrode configuration of a solar cell according to Variation 12 of Embodiment 2.

### DETAILED DESCRIPTION OF THE EMBODIMENTS

The following describes in detail a solar cell module according to embodiments of the present disclosure with reference to the drawings. The embodiments described below each illustrate a particular example of the present disclosure. Thus, the numerical values, shapes, materials, elements, the arrangement and connection of the elements, and others indicated in the following embodiments are mere examples, and are not intended to limit the present disclosure. Therefore, among the elements in the following embodiments, elements not recited in any of the independent claims defining the most generic part of the present disclosure are described as arbitrary elements.

The drawings are schematic diagrams and do not necessarily give strict illustration. Throughout the drawings, the same sign is given to the same element.

In the written description, a “front surface” of a solar cell means a surface through which more light enters the solar cell than light that enters the solar cell through a “back surface” located on the opposite side of the front surface (more than 50% to 100% of light enters the solar cell through the front surface), and there is also a case where no light enters the solar cell from the “back surface” side. A “front surface” of a solar cell module means a surface located on a side facing the “front surface” of the solar cell and through which light enters, and the “back surface” means a surface located on the opposite side of the front surface. Furthermore, the statement such as “a second member is disposed on a first member” does not necessarily mean that the first member and the second member are in direct contact, unless specifically limited. Thus, this statement includes the case where another member is present between the first member and the second member. In addition, the statement “approximately XX” is intended to mean, when using “approximately the same” as an example, not only completely the same, but also something that can be recognized as substantially the same.

### Embodiment 1

### [1-1. Basic Configuration of Solar Cell Module]

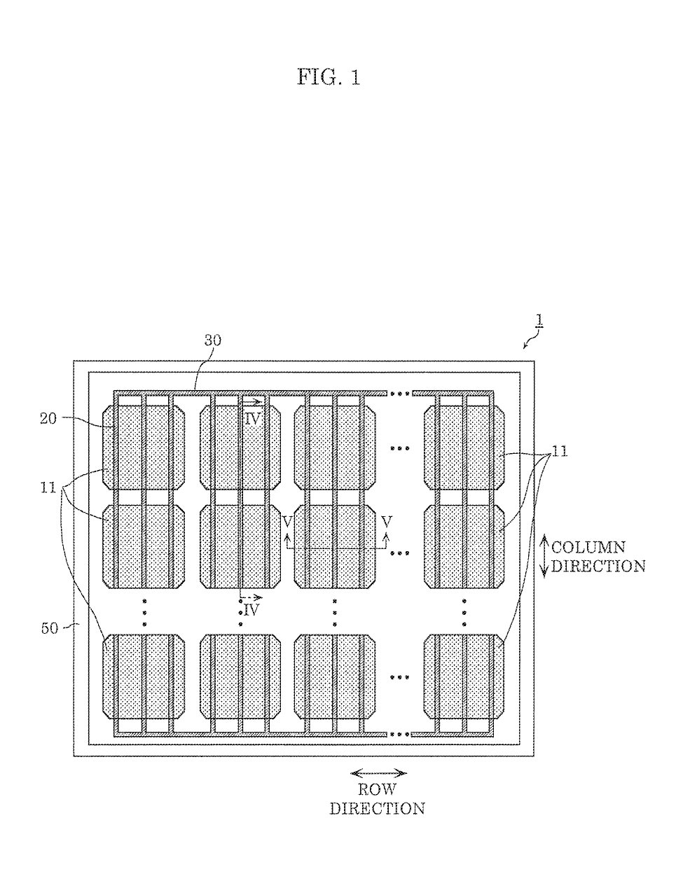

An example of a basic configuration of a solar cell module according to the present embodiment is described with reference to FIG. 1.

FIG. 1 is a schematic plan view of solar cell module 1 according to Embodiment 1. Solar cell module 1 illustrated in FIG. 1 includes solar cells 11, tab lines 20, connecting lines 30, and frame 50.

Solar cells 11 are disposed two dimensionally on a light receiving surface of solar cell module 1, and are plate-like photovoltaic cells which generate power by being irradiated with light.

Tab line 20 is a wiring member which is disposed on the surfaces of solar cells 11, and electrically connects solar cells 11 adjacent in the column direction. Note that tab line 20 may have a light diffusing shape on the light entering side. The light diffusing shape is a shape having a light diffusing function. The light diffusing shape diffuses, on the surface of tab line 20, light which has fallen on tab line 20, and causes the diffused light to be redistributed to solar cell 11.

Connecting line 30 is a wiring member which connects solar cell strings. Note that a solar cell string is an aggregate of solar cells 11 disposed in the column direction and connected by tab lines 20. Note that connecting line 30 may have the light diffusing shape on a surface on the light entering side. Accordingly, light which has entered between solar cell 11 and frame 50 can be diffused on the surface of connecting line 30, and the diffused light can be redistributed to solar cell 11.

Frame 50 is an outer frame member which covers a perimeter portion of a panel on which solar cells 11 are two-dimensionally disposed.

Although not illustrated, a light diffusing member may be disposed between adjacent solar cells 11. Accordingly, light which has entered a space between solar cells 11 can be redistributed to solar cells 11, and thus light concentrating efficiency of solar cells 11 improves. Accordingly, the photoelectric conversion efficiency of the entire solar cell module can be improved.

### [1-2. Structure of Solar Cell]

A description of a structure of solar cell 11 which is a main component of solar cell module 1 is given.

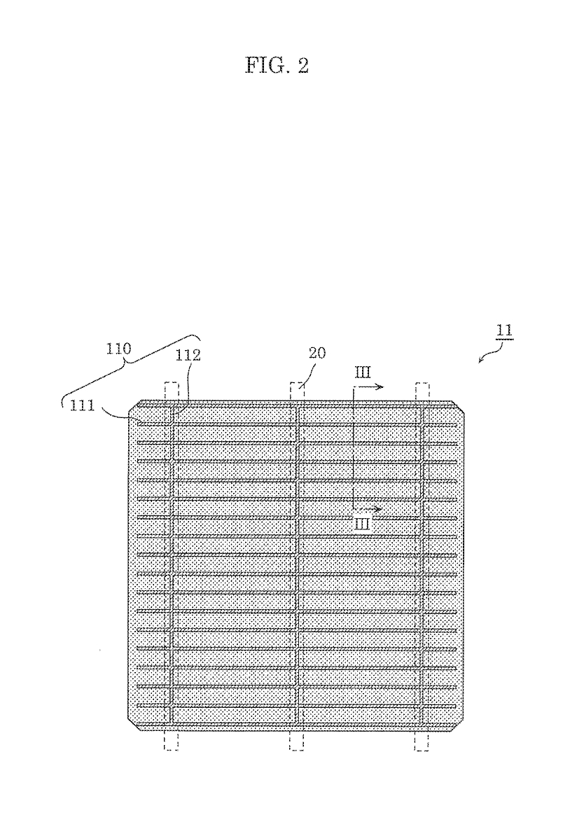

FIG. 2 is a plan view of solar cell 11 according to Embodiment 1. As illustrated in FIG. 2, solar cell 11 is approximately square in the plan view. For example, solar cell 11 has a length of 125 mm, a width of 125 mm, and a thickness of 200 μm. On a surface of solar cell 11, bus bar electrodes 112 in stripes are formed in parallel to one another, and finger electrodes 111 in stripes are formed in parallel to one another, perpendicularly to bus bar electrodes 112. Bus bar electrodes 112 and finger electrodes 111 constitute collector electrode 110. Collector electrode 110 is formed using an electrically conductive paste which contains electrically conductive particles such as Ag (silver), for example. Note that the line width of bus bar electrodes 112 is, for example, 150 μm, and the line width of finger electrodes 111 is, for example, 100 μm. The spacing between finger electrodes 111 is 2 mm, for example. Tab lines 20 are bonded onto bus bar electrodes 112.

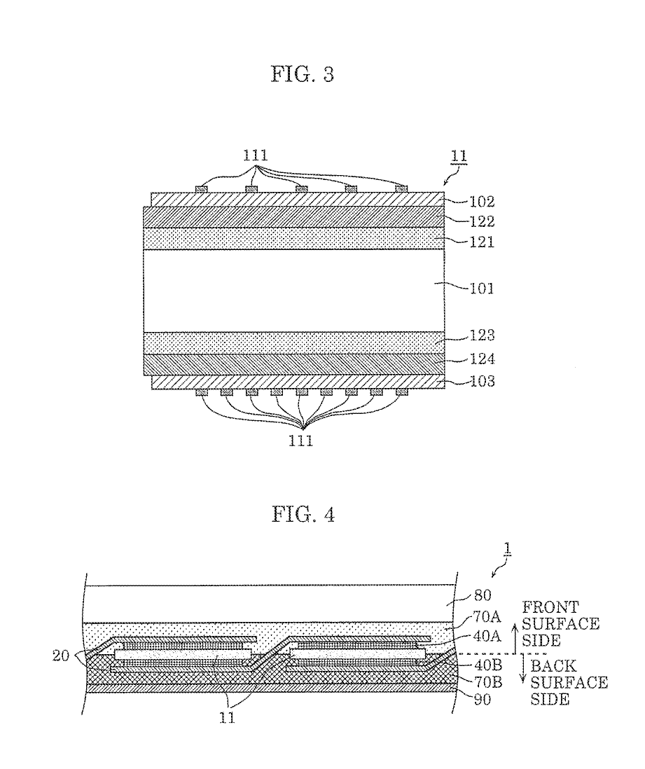

FIG. 3 is a cross-sectional view illustrating a stack structure of solar cell 11 according to Embodiment 1. Note that FIG. 3 is a cross-sectional view of solar cell 11 taken along III-III in FIG. 2. As illustrated in FIG. 3, i-type amorphous silicon film 121 and p-type amorphous silicon film 122 are formed in the stated order on the principal surface of n-type monocrystalline silicon wafer 101. N-type monocrystalline silicon wafer 101, i-type amorphous silicon film 121, and p-type amorphous silicon film 122 form a photoelectric conversion layer, and n-type monocrystalline silicon wafer 101 serves as a main power generation layer. Furthermore, light-receiving surface electrode 102 is formed on p-type amorphous silicon film 122. As illustrated in FIG. 2, collector electrode 110 constituted by bus bar electrodes 112 and finger electrodes 111 is formed on light-receiving surface electrode 102. Note that in FIG. 3, only finger electrodes 111 of collector electrode 110 are illustrated.

I-type amorphous silicon film 123 and n-type amorphous silicon film 124 are formed in this order on the back surface of n-type monocrystalline silicon wafer 101. Furthermore, light-receiving surface electrode 103 is formed on n-type amorphous silicon film 124, and collector electrode 110 constituted by bus bar electrodes 112 and finger electrodes 111 is formed on light-receiving surface electrode 103.

Note that p-type amorphous silicon film 122 may be formed on the back surface side of n-type monocrystalline silicon wafer 101, and n-type amorphous silicon film 124 may be formed on the light-receiving surface side of n-type monocrystalline silicon wafer 101.

Collector electrode 110 may be formed by a printing method such as, for example, screen printing, using a thermosetting, electrically conductive resin paste obtained using a resin material as a binder and electrically conductive particles such as silver particles as filler.

Note that as illustrated in FIG. 3, the spacing between finger electrodes 111 on the back surface may be smaller than the spacing between finger electrodes 111 on the front surface. In other words, the number of finger electrodes 111 on the back surface may be greater than the number of finger electrodes on the front surface. Specifically, the surface area occupancy of the collector electrode formed on the back surface may be higher than the surface area occupancy of the collector electrode formed on the front surface. Here, the surface area occupancy of the collector electrode is a proportion of a total area of bus bar electrodes 112 and finger electrodes 111 in a plan view with respect to the area of solar cell 11 in the plan view.

In the case of the above arrangement of the electrodes on the back surface, the efficiency of collecting current on the back surface increases, while more light is prevented from entering through the back surface than light prevented from entering through the front surface. However, solar cell 11 according to the present embodiment is a mono-facial element whose light-receiving surface is a front surface, and thus an increase in the current collecting efficiency on the back surface has greater influence than an increase in the amount of light prevented from entering through the back surface. Accordingly, advantageous effects of collecting current achieved by solar cell 11 can be improved.

Solar cell 11 according to the present embodiment has a structure in which i-type amorphous silicon film 121 is included between n-type monocrystalline silicon wafer 101 and p-type amorphous silicon film 122, and i-type amorphous silicon film 123 is included between n-type monocrystalline silicon wafer 101 and n-type amorphous silicon film 124, in order to improve p-n junction properties.

Solar cell 11 according to the present embodiment is a mono-facial element, and light-receiving surface electrode 102 on the front surface side of n-type monocrystalline silicon wafer 101 serves as a light-receiving surface. Charge carriers generated in n-type monocrystalline silicon wafer 101 are diffused as photocurrent to light-receiving surface electrodes 102 and 103 on the front surface side and the back surface side, and collected by collector electrodes 110.

Light-receiving surface electrodes 102 and 103 are, for example, transparent electrodes made of indium tin oxide (ITO), tin oxide (SnO₂), and zinc oxide (ZnO), for instance. Note that light-receiving surface electrode 103 on the back surface side may be a metal electrode which is not transparent. Further, an electrode formed on the entire surface on light-receiving surface electrode 103 may be used as a collector electrode on the back surface side, instead of collector electrode 110.

Note that the solar cell according to the present embodiment may be a bifacial element. In this case, light-receiving surface electrode 102 on the front surface side of n-type monocrystalline silicon wafer 101 and light-receiving surface electrode 103 on the back surface side of n-type monocrystalline silicon wafer 101 both serve as light-receiving surfaces. Charge carriers generated in n-type monocrystalline silicon wafer 101 are diffused as photoelectric current to light-receiving surface electrodes 102 and 103 on the front surface side and the back surface side, and collected by collector electrodes 110. Light-receiving surface electrodes 102 and 103 are transparent electrodes.

### [1-3. Structure of Solar Cell Module]

The following describes a specific structure of solar cell module 1 according to the present embodiment.

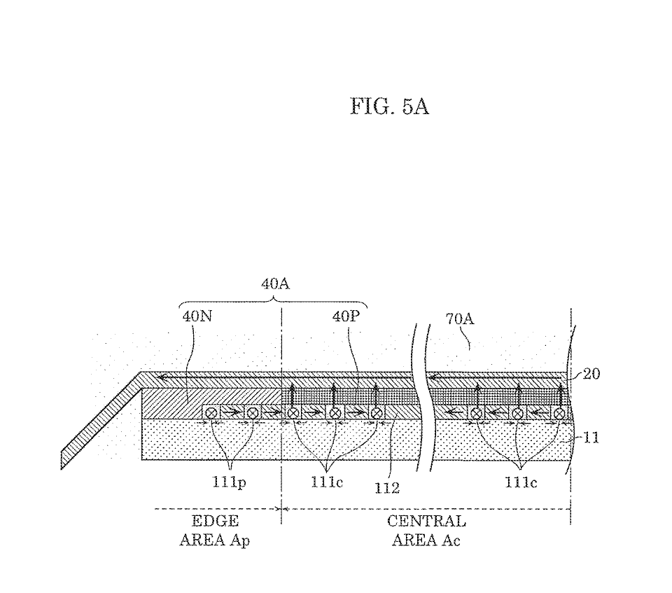

FIG. 4 is a cross-sectional view of a structure of the solar cell module according to Embodiment 1 in the column direction. Specifically, FIG. 4 is a cross-sectional view of solar cell module 1 taken along line IV-IV in FIG. 1. Solar cell module 1 illustrated in FIG. 4 includes solar cells 11, tab lines 20, electrically conductive bonding members 40A and 40B, front surface filler 70A, back surface filler 70B, front surface shield 80, and back surface shield 90.

Tab lines 20 are electrically conductive elongated lines, and are ribbon-shaped metallic foil, for example. Tab lines 20 can be produced by cutting, for example, metallic foil, such as copper foil or silver foil having surfaces entirely covered with solder, silver, or the like into strips having a predetermined length. In two solar cells 11 adjacent in the column direction, tab line 20 disposed on the front surface of one of solar cells 11 is also disposed on the back surface of the other of solar cells 11. More specifically, the undersurface of tab line 20 at an end portion is connected with bus bar electrode 112 (see FIG. 2) on the front surface side of one of solar cells 11. The upper surface of tab line 20 at the other end portion is connected with a bus bar electrode (not illustrated) on the back surface side of the other of solar cells 11. Accordingly, a solar cell string made up of solar cells 11 disposed in the column direction has a configuration in which solar cells 11 are connected in series in the column direction.

Tab lines 20 and bus bar electrodes 112 (see FIG. 2) are connected by electrically conductive bonding members 40A and 40B. Stated differently, tab line 20 is connected with solar cell 11 via an electrically conductive bonding member.

As electrically conductive bonding members 40A and 40B, an electrically conductive adhesive paste, an electrically conductive glue film, or an anisotropic electrically conductive film can be used, for example. Electrically conductive adhesive paste is a pasty adhesive obtained by dispersing electrically conductive particles into a thermosetting adhesive resin material such as an epoxy resin, an acrylic resin, or a urethane resin, for example. An electrically conductive glue film and an anisotropic electrically conductive film are obtained by dispersing electrically conductive particles into a thermosetting adhesive resin material and forming the material into films.

Note that electrically conductive bonding members 40A and 40B may be solder material, rather than the electrically conductive adhesive mentioned above as an example. Furthermore, a resin adhesive which does not include electrically conductive particles may be used, instead of the electrically conductive adhesive. In this case, by appropriately designing the thickness of an applied resin adhesive, a resin adhesive softens when pressure is applied for thermo compression bonding, and consequently the surface of bus bar electrode 112 and tab line 20 are brought into direct contact and electrically connected.

As illustrated in FIG. 4, front surface shield 80 is disposed on the front surface side of solar cells 11, and back surface shield 90 is disposed on the back surface side. Front surface filler 70A is included between a plane which includes solar cells 11 and front surface shield 80, and back surface filler 70B is included between a plane which includes solar cells 11 and back surface shield 90. Front surface shield 80 and back surface shield 90 are fixed by front surface filler 70A and back surface filler 70B, respectively.

Front surface shield 80 is a shield disposed on the front surface side of solar cell 11. Front surface shield 80 protects the inside of solar cell module 1 from rainstorm, external shock, fire, and so on, and is a member for securing long term reliability against outdoor exposure of solar cell module 1. From this viewpoint, for example, light-transmitting waterproof glass, or a light-transmitting waterproof hard resin member having a film or plate shape, for instance, can be used for front surface shield 80.

Back surface shield 90 is a shield disposed on the back surface side of solar cell 11. Back surface shield 90 is a member which protects the back surface of solar cell module 1 from the outside environment, and for example, a laminated film which has a structure in which a resin film such as a polyethylene terephthalate film or an Al foil is sandwiched by resin films.

Front surface filler 70A fills a space between front surface shield 80 and solar cells 11. Back surface filler 70B fills a space between back surface shield 90 and solar cells 11. Front surface filler 70A and back surface filler 70B have a sealing function for separating solar cells 11 from the outside environment. Disposing front surface filler 70A and back surface filler 70B secures high heat resistance and high moisture resistance of solar cell module 1 which is assumed to be installed outside.

Front surface filler 70A is made of a light-transmitting polymer material which has a sealing function. An example of the polymer material of front surface filler 70A is a light-transmitting resin material such as ethylene vinyl acetate (EVA).

Back surface filler 70B is made of a polymer material having a sealing function. Here, back surface filler 70B is subjected to white processing. An example of the polymer material for back surface filler 70B is a resin material which includes EVA that has been subjected to white processing.

Note that front surface filler 70A and back surface filler 70B may be based on the same material, in order to simplify a manufacturing process and the adhesion at the interface between front surface filler 70A and back surface filler 70B. Front surface filler 70A and back surface filler 70B are formed by performing lamination processing on (laminating) two resin sheets (light-transmitting EVA sheet and EVA sheet that has been subjected to white processing) between which solar cells 11 (cell strings) are disposed.

### [1-4. Bonding Structure of Tab Line and Solar Cell]

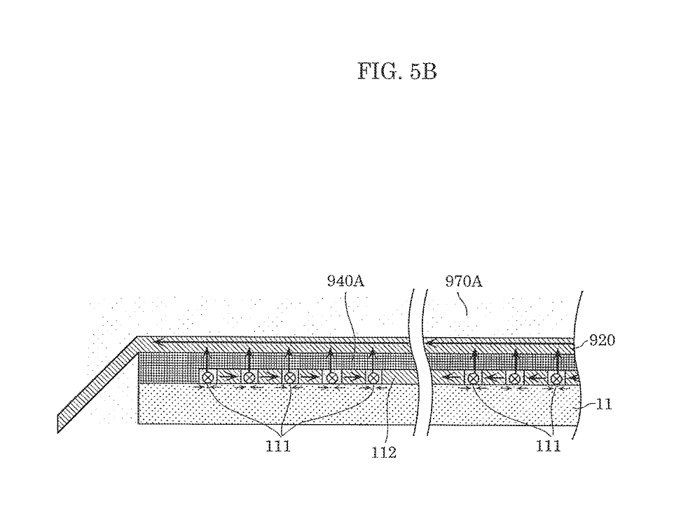

FIG. 5A is a structural cross-sectional view illustrating a flow of electric charges from received light in solar cell 11 according to Embodiment 1. More specifically, FIG. 5A is an enlarged cross-sectional view of a portion around the front surface of solar cell 11 in the structural cross-sectional view in FIG. 4. As illustrated in FIG. 5A, bus bar electrode 112 and tab line 20 are bonded to each other by electrically conductive bonding member 40A.

FIG. 5B is a structural cross-sectional view illustrating a flow of electric charges from received light in a conventional solar cell. As illustrated in FIG. 5B, in the conventional solar cell module, solar cell 11 and tab line 920 are uniformly bonded to each other on the entirety of solar cell 11 in the longitudinal direction of tab line 920, via electrically conductive bonding member 940A. Accordingly, stress may be applied to tab line 920 between solar cells by repeated expansion and contraction of solar cell 11 and tab line 920 due to temperature cycling.

On the other hand, a feature of solar cell module 1 according to the present embodiment is that the bonding strength between solar cell 11 and tab line 20 in edge region Ap on a side where tab line 20 is formed of solar cell 11 is lower than the bonding strength between solar cell 11 and tab line 20 in central area Ac of solar cell 11. Since the bonding strength is set as stated above, even if solar cell 11 and tab line 20 repeatedly expand and contract due to temperature cycling, stress applied to tab line 20 between solar cells can be reduced. Here, edge area Ap is a first edge area of a perimeter area of solar cell 11, which is on a side where solar cell 11 is electrically connected with another solar cell 11 by tab line 20.

The above description is focused on edge area Ap of the front surface of solar cell 11 on a side where tab line 20 is formed, yet the bonding strength of tab line 20 on the back surface in edge area Ap on a side where tab line 20 is formed may be lower than the bonding strength in central area Ac. On only the front surface side, or on only the back surface side, or even on both sides, the bonding strength in edge area Ap on a side where tab line 20 is formed may be lower than the bonding strength in central area Ac. Furthermore, the bonding strength also in an edge area on a side where tab line 20 is not formed in addition to the side where tab line 20 is formed may be lower than central area Ac. In this case, for example, even when a solar cell is disposed upside down, advantageous effects of the present disclosure can be achieved, and thus yield when creating modules is expected to improve. Hereinafter, edge area Ap indicates an edge area of a front surface or a back surface on a side where tab line 20 is formed.

Note that due to a relation of the bonding strength in edge area Ap and 20 central area Ac, solar cell 11 and tab line 20 in central area Ac are bonded to each other in an electrically conductive state via bonding portion 40P, whereas solar cell 11 and tab line 20 in edge area Ap are bonded to each other in an electrically nonconductive state via bonding portion 40N. Accordingly, electric charges from received light which are collected by finger electrodes 111p formed 25 in edge area Ap are not transferred to tab line 20 via bonding portion 40N immediately above. However, solar cell module 1 according to the present embodiment has a configuration of efficiently collecting electric charges from received light which are collected in edge area Ap, via bus bar electrode 112 and bonding portion 40P in central area Ac.

The following describes in detail a configuration of improving efficiency of collecting current by collector electrode 110 while reducing stress applied to tab line 20.

### [1-5. Configuration of Collector Electrode According to Embodiment 1]

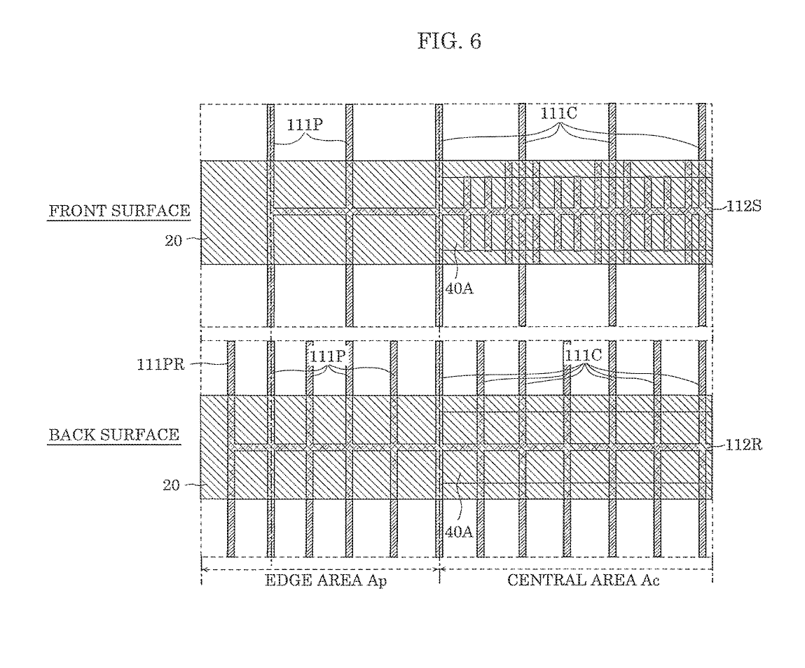

FIG. 6 shows plan views illustrating an electrode configuration of solar cell 11 according to Embodiment 1 on a front surface side and a back surface side. More specifically, FIG. 6 shows enlarged perspective plan views of the front surface and the back surface of solar cell 11 in the structural cross-sectional view in FIG. 4.

As illustrated in FIG. 6, bus bar electrode 112S and finger electrodes 111C perpendicular to bus bar electrode 112S and parallel to one another are disposed in central area Ac on the front surface of solar cell 11. Electrically conductive bonding member 40A which bonds tab line 20 to bus bar electrode 112S is disposed in central area Ac on the front surface of solar cell 11. Note that short electrode groups for securing the bonding strength between tab line 20 and solar cell 11 are disposed between finger electrodes 111C. Bus bar electrode 112S and finger electrodes 111P perpendicular to bus bar electrode 112S and parallel to one another are disposed in edge area Ap on the front surface of solar cell 11.

On the back surface of solar cell 11, bus bar electrode 112R and finger electrodes 111C perpendicular to bus bar electrode 112R and parallel to one another are disposed in central area Ac. Electrically conductive bonding member 40A which bonds tab line 20 to bus bar electrode 112R is disposed in central area Ac on the back surface of solar cell 11. Bus bar electrode 112R and finger electrodes 111P and finger electrode 111PR which are perpendicular to bus bar electrode 112R and parallel to one another are disposed in edge area Ap on the back surface of solar cell 11. Finger electrode 111PR is formed closest to the edge among finger electrodes 111P disposed in edge area Ap on the back surface. Note that a plurality of finger electrodes 111PR may be disposed. The spacing between finger electrodes 111PR and the spacing between finger electrode 111PR and another finger electrode may be different from the spacing between finger electrodes 111C and the spacing between finger electrodes 111P.

Note that in the present embodiment and the variations described below, finger electrodes cross a bus bar electrode in a plan view, and disposed approximately parallel to one another. Accordingly, the finger electrodes have a function of transferring electric charges from received light generated by solar cell 11 to the bus bar electrode.

In the present embodiment and the variations described below, a bus bar electrode is disposed in central area Ac, crossing finger electrodes, and bonded to tab line 20 via electrically conductive bonding member 40A in central area Ac. Accordingly, the bus bar electrode has a function of transferring electric charges from received light which are collected by the finger electrodes to tab line 20. The bus bar electrode is defined to include an electrode which is directly connected with the bus bar electrode disposed in central area Ac and crosses a finger electrode in edge area Ap, and exclude an electrode in edge area Ap connected with the bus bar electrode disposed in central area Ac via a line extending in a direction in which a finger electrode is formed.

Here, bus bar electrodes 112S and 112R are formed in both edge area Ap and central area Ac. In contrast, electrically conductive bonding members 40A are disposed only in central area Ac among edge area Ap and central area Ac. Specifically, the lengths of electrically conductive bonding members 40A in the longitudinal direction of tab lines 20 are shorter than the lengths of bus bar electrodes 112S and 112R in the longitudinal direction of tab lines 20.

Accordingly, tab lines 20 are bonded to solar cell 11 only in central area Ac, and thus stress applied to tab lines 20 between solar cells 11 can be reduced even if solar cell 11 and tab lines 20 repeatedly expand and contract due to temperature cycling.

Bus bar electrode 112R formed on the back surface is longer toward the edge of solar cell 11 than bus bar electrode 112S formed on the front surface is. Finger electrode 111PR formed on the back surface is closer to the edge of solar cell 11 than outermost finger electrode 111P among finger electrodes formed on the front surface. In the case of the above electrode arrangement on the back surface, the current collecting efficiency on the back surface increases, but more light is prevented from entering through the back surface than light prevented from entering through the front surface. However, solar cell 11 according to the present embodiment is a mono-facial element whose front surface is the light-receiving surface, and thus an increase in the current collecting efficiency on the back surface gives more influence than the influence of an increase in the amount of light prevented from entering through the back surface. This allows solar cell 11 to yield more advantageous effects of collecting current. Note that a plurality of finger electrodes 111PR may be disposed. The spacing between finger electrodes 111PR and the spacing between finger electrode 111PR and another finger electrode may be different from the spacing between finger electrodes 111C and the spacing between finger electrodes 111P.

### [1-6. Configuration of Collector Electrode According to Variation 1 of Embodiment 1]

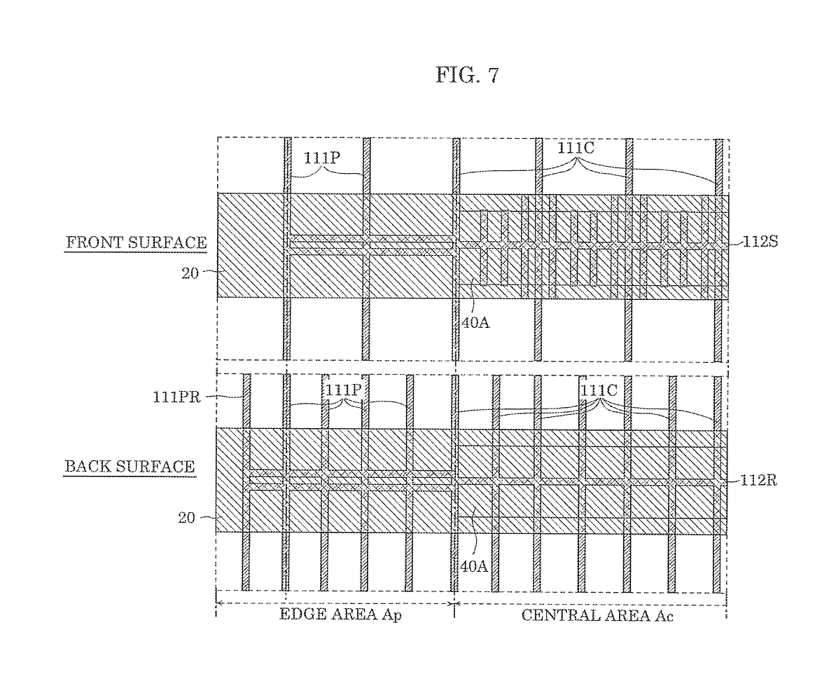

FIG. 7 shows plan views illustrating an electrode configuration of solar cell 11 according to Variation 1 of Embodiment 1 on a front surface side and a back surface side. More specifically, FIG. 7 shows enlarged perspective plan views of the front surface and the back surface of solar cell 11 in the structural cross-sectional view in FIG. 4. The electrode configuration of solar cell 11 according to this variation is different from the electrode configuration of solar cell 11 illustrated in FIG. 6, only in the configuration of bus bar electrodes in edge area Ap. The following description focuses on differences from the electrode configuration of solar cell 11 illustrated in FIG. 6 while a description of the same points is omitted.

As illustrated in FIG. 7, bus bar electrode 112S according to this variation includes two electrodes parallel to each other in edge area Ap. The widths of the two electrodes are each approximately the same as the width of bus bar electrode 112S in central area Ac. Specifically, a resistance per unit length of bus bar electrode 112S in edge area Ap is lower than the resistance per unit length of bus bar electrode 112S in central area Ap. The same applies to bus bar electrode 112R according to this variation, and a resistance per unit length of bus bar electrode 112R in edge area Ap is lower than a resistance per unit length of bus bar electrode 112R in central area Ap.

As illustrated in FIG. 7, bus bar electrodes 112S and 112R are not bonded to tab lines 20 in edge area Ap. Electric charges from received light collected by all finger electrodes 111P disposed in edge area Ap are transferred to tab lines 20 via the bus bar electrodes in edge area Ap. According to the electrode configuration described above, the electric charges from received light collected in edge area Ap are transferred to tab lines 20 via the bus bar electrodes in edge area Ap where resistance loss is relatively low, and thus the current collecting efficiency of solar cell 11 can be increased.

Note that in this variation, a resistance per unit length of bus bar electrodes 112S and 112R in edge area Ap is each decreased by disposing two parallel electrodes in edge area Ap, yet the present disclosure is not limited to this. For example, the bus bar electrodes in edge area Ap may be each achieved by using one electrode wider than the bus bar electrode in central area Ac, rather than by using two parallel electrodes. The thickness of a bus bar electrode in edge area Ap may be greater than the thickness of the bus bar electrode in central area Ac.

### [1-7. Configuration of Collector Electrode According to Variation 2 of Embodiment 1]

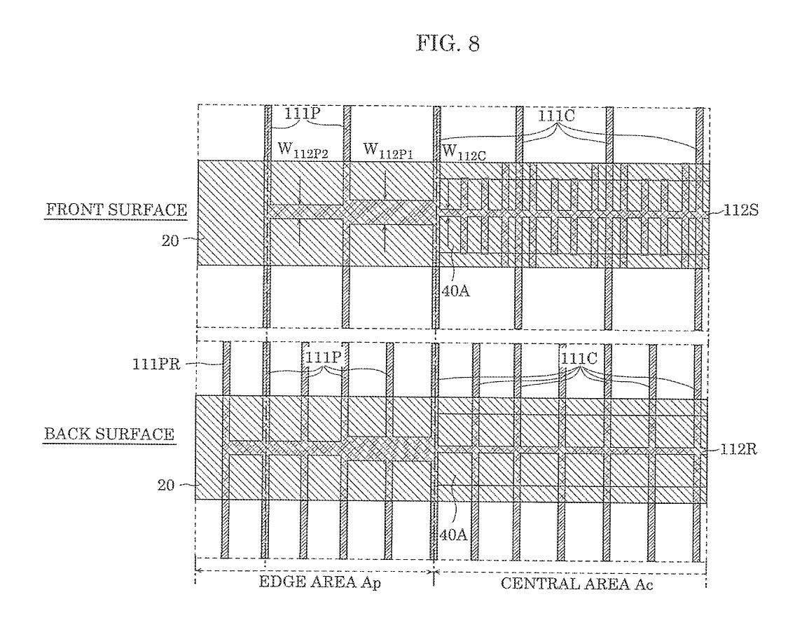

FIG. 8 shows plan views illustrating an electrode configuration of solar cell 11 according to Variation 2 of Embodiment 1 on a front surface side and a back surface side. More specifically, FIG. 8 shows enlarged perspective plan views of the front surface and the back surface of solar cell 11 in the structural cross-sectional view in FIG. 4. The electrode configuration of solar cell 11 according to this variation is different from the electrode configuration of solar cell 11 illustrated in FIG. 6, only in the configuration of bus bar electrodes in edge area Ap. The following description focuses on differences from the electrode configuration of solar cell 11 illustrated in FIG. 6 while a description of the same points is omitted.

As illustrated in FIG. 8, bus bar electrode 112S according to this variation has a greater width in edge area Ap than the width in central area Ac. In edge area Ap, width W_{112P1} of bus bar electrode 112S in an area closer to central area Ac is greater than width W_{112P2} of bus bar electrode 112S in an area farther from central area Ac than the area closer to central area Ac is. The same applies to bus bar electrode 112R on the back surface, and in edge area Ap, the width of bus bar electrode 112R in an area closer to central area Ac is greater than the width of bus bar electrode 112R in an area farther from central area Ac than the area closer to central area Ac is. Stated differently, in edge area Ap, resistances per unit length of portions of bus bar electrodes 112S and 112R closer to central area Ac are lower than resistances per unit length of portions of bus bar electrodes 112S and 112R farther from central area Ac.

As illustrated in FIG. 8, bus bar electrodes 112S and 112R are not bonded to tab lines 20 in edge area Ap. Thus, electric charges from received light collected by finger electrodes 111P disposed in edge area Ap are transferred to tab lines 20 via the bus bar electrodes in edge area Ap. According to the electrode configuration described above, the electric charges from received light collected in edge area Ap are transferred to tab lines 20 via the bus bar electrodes in edge area Ap where resistance loss is relatively low. Thus, the current collecting efficiency of solar cell 11 can be improved. Furthermore, with regard to the bus bar electrodes in edge area Ap, the amount of electric charges from received light collected in edge area Ap increases toward central area Ac. In view of this, in edge area Ap, resistances per unit length of portions of the bus bar electrodes closer to central area Ac are lower than resistances per unit length of portions of the bus bar electrodes farther from central area Ac. Accordingly, the resistance loss in edge area Ap can be decreased, and the current collecting efficiency of solar cell 11 is further improved.

### [1-8. Configuration of Collector Electrode According to Variation 3 of Embodiment 1]

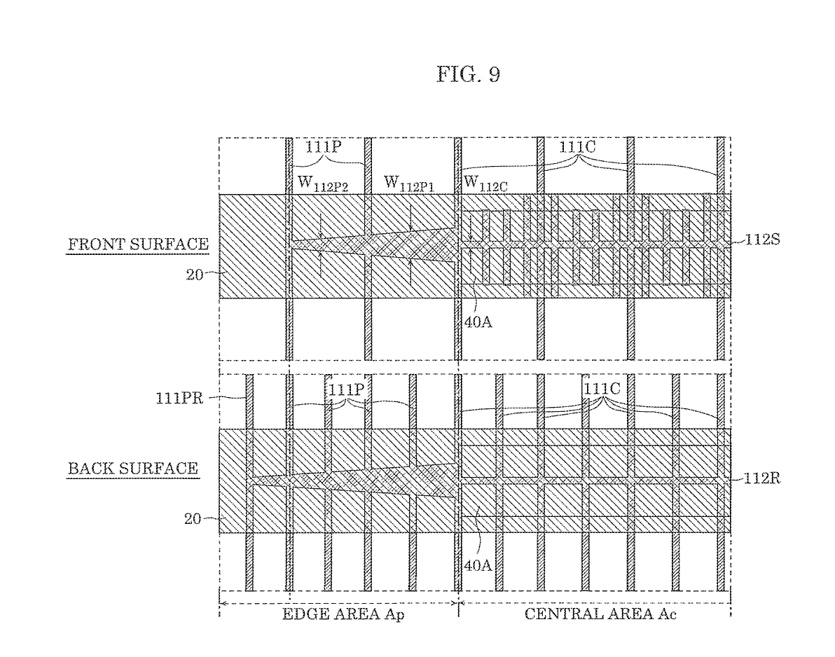

FIG. 9 shows plan views illustrating an electrode configuration of solar cell 11 according to Variation 3 of Embodiment 1 on a front surface side and a back surface side. More specifically, FIG. 9 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 2 illustrated in FIG. 8, only in the configuration of bus bar electrodes in edge area Ap. The following description focuses on differences from the electrode configuration of solar cell 11 illustrated in FIG. 6 while a description of the same points is omitted.

As illustrated in FIG. 9, bus bar electrode 112S according to this variation has a greater width in edge area Ap than the width in central area Ac. In edge area Ap, width W_{112P1} of bus bar electrode 112S in an area closer to central area Ac is greater than width W_{12P2} of bus bar electrode 112S in an area farther from central area Ac than the area closer to central area Ac is. Bus bar electrode 112S in edge area Ap has an inversely tapered shape gradually wider toward central area Ac in the plan view. Furthermore, the same applies to bus bar electrode 112R on the back surface, and bus bar electrode 112R in edge area Ap has an inversely tapered shape gradually wider toward central area Ac in the plan view.

According to this, similarly to solar cell 11 according to Variation 2, electric charges from received light collected in edge area Ap are transferred to tab lines 20 via the bus bar electrodes in edge area Ap where resistance loss is relatively small, and thus current collecting efficiency of solar cell 11 is improved. Furthermore, resistances per unit length of the bus bar electrodes in edge area Ap are gradually decreased toward central area Ac, and thus resistance loss in edge area Ap can be more effectively decreased. Accordingly, the current collecting efficiency of solar cell 11 is further improved.

### [1-9. Resistance Loss Depending on Configuration of Collector Electrode According to Embodiment 1]

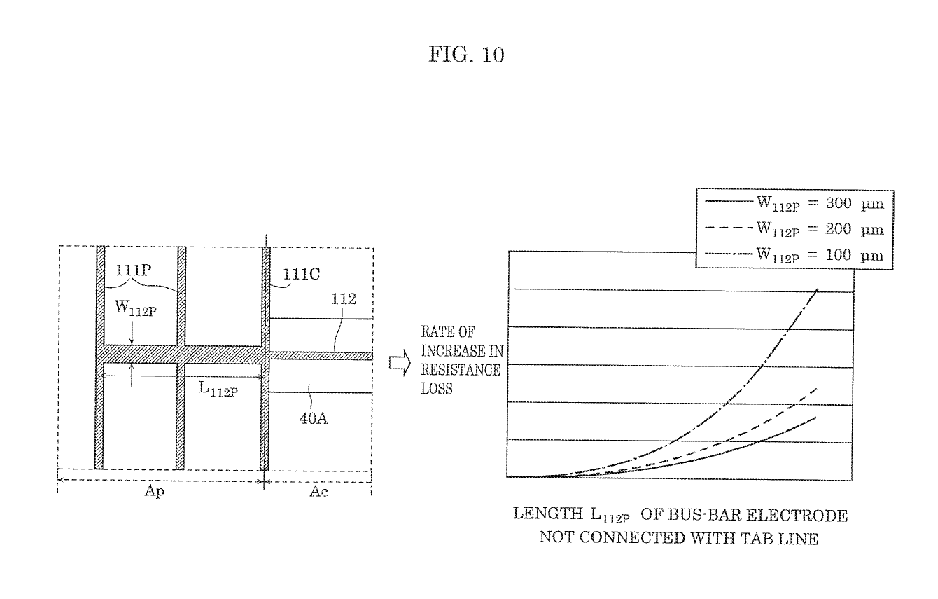

FIG. 10 illustrates effects of resistance loss depending on an electrode configuration according to Embodiment 1. More specifically, FIG. 10 illustrates, on the left, an enlarged plan view showing an electrode configuration on the front surface of solar cell 11 and, on the right, a graph showing a relation between the width of a bus bar electrode and resistance loss.

In the plan view in FIG. 10, bus bar electrode 112 is formed on both edge area Ap and central area Ac. Electrically conductive bonding member 40A is, however, disposed only in central area Ac, among edge area Ap and central area Ac. Specifically, the longitudinal length of electrically conductive bonding member 40A is shorter than the length of bus bar electrode 112. Here, the width of bus bar electrode 112 in edge area Ap is W_{112P}, and the length of bus bar electrode 112 in edge area Ap is L_{112P}.

The graph in FIG. 10 shows a relation between resistance loss that occurs in bus bar electrode 112 and length L_{112P} of bus bar electrode 112 when electrode width W_{112P} is changed. Note that a rate of increase in resistance loss of bus bar electrode 112 indicated by the vertical axis is a proportion to resistance loss when the width of bus bar electrode 112 is uniform along the longitudinal direction. As illustrated in the graph in FIG. 10, the longer length L_{112P} of bus bar electrode 112 in edge area Ap not connected with tab line 20 is, the greater the resistance loss that occurs in bus bar electrode 112 is. In contrast, the greater width W_{112P} of bus bar electrode 112 in edge area Ap not connected with tab line 20 is, the less the resistance loss that occurs in bus bar electrode 112 is.

In the present embodiment, in order to reduce stress applied to tab line 20 due to temperature cycling, the longitudinal length of electrically conductive bonding member 40A is shorter than the length of bus bar electrode 112. Instead, length L_{112P} of bus bar electrode 112 not connected to tab line 20 is increased, and thus the resistance loss that occurs in bus bar electrode 112 increases. In contrast, resistance loss that occurs in bus bar electrode 112 can be reduced by making width W_{112P} of bus bar electrode 112 in edge area Ap, which is not connected with tab line 20, greater than the width of bus bar electrode 112 in central area Ac. Thus, current collecting efficiency can be improved while reducing stress applied to tab line 20 between solar cells 11.

### Embodiment 2

A solar cell module according to the present embodiment has a feature that the bonding strength between solar cell 11 and tab line 20 in edge area Ap of solar cell 11 is lower than the bonding strength between solar cell 11 and tab line 20 in central area Ac of solar cell 11, similarly to the solar cell module according to the above embodiment. In order to achieve this, the longitudinal length of electrically conductive bonding member 40A is made shorter than the length of bus bar electrode 112 in Embodiment 1, whereas in the present embodiment, in the longitudinal direction of tab line 20, the shortest distance between the edge of solar cell 11 and a finger electrode closest to the edge of solar cell 11 on a side where tab line 20 is formed is made shorter than the distance between the edge of solar cell 11 and an end of the bus bar electrode on the side where tab line 20 is formed. Accordingly, even if electrically conductive bonding member 40A is present in edge area Ap, an area where electrically conductive bonding member 40A and an electrode are bonded to each other is decreased, and thus the bonding strength in edge area Ap can be decreased. Thus, the bonding strength between solar cell 11 and tab line 20 can be decreased irrespective of the length of electrically conductive bonding member 40A in the longitudinal direction. In the following embodiments, a bonding length in the longitudinal direction of tab line 20 along which bus bar electrode 112 and tab line 20 are bonded together is shorter than the length of electrically conductive bonding member 40A in the longitudinal direction.

The basic configuration, a cross-sectional configuration, and others of the solar cell module according to the present embodiment are the same as those in Embodiment 1, and thus a description thereof is omitted. The following gives a description focusing on an electrode configuration of solar cell 11 different from the electrode configuration in Embodiment 1.

### [2-1. Configuration of Collector Electrode According to Embodiment 2]

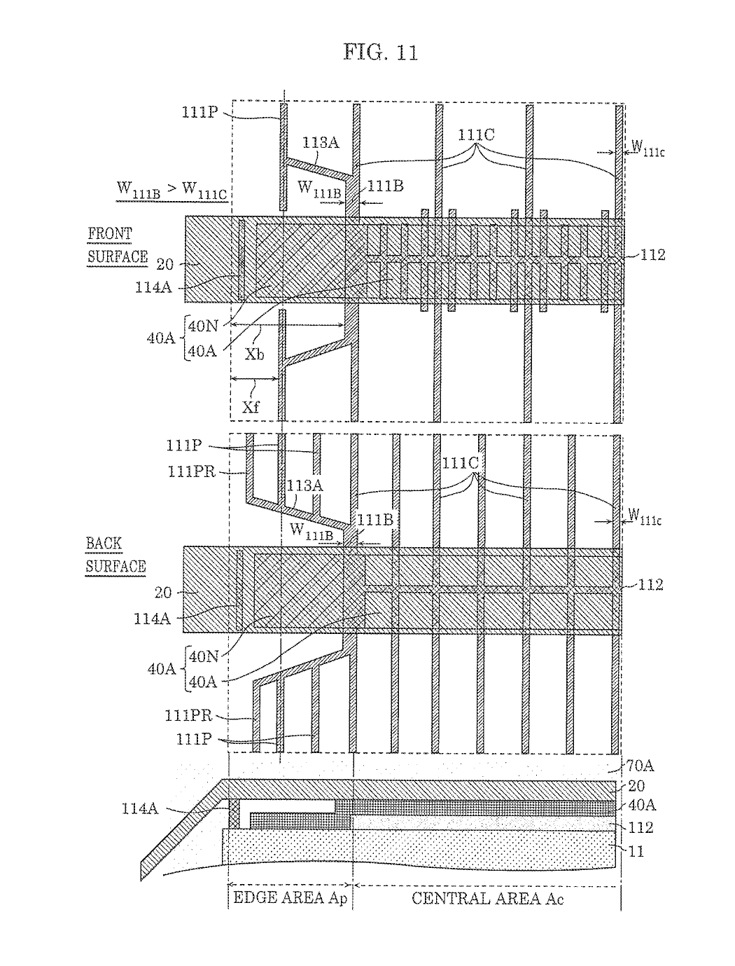

FIG. 11 shows plan views and a cross-sectional view illustrating an electrode configuration of solar cell 11 according to Embodiment 2. More specifically, FIG. 11 shows enlarged perspective plan views of the front surface and the back surface of solar cell 11 in the structural cross-sectional view in FIG. 4, and an enlarged cross-sectional view of a portion around the front 10 surface of solar cell 11.

As illustrated in the cross-sectional view in FIG. 11, electrically conductive bonding members 40A bond tab lines 20 to solar cell 11 by bonding tab lines 20 to bus bar electrodes 112. As illustrated in the plan view on the front surface side and the plan view on the back surface side in FIG. 11, bus bar electrode 112 and finger electrodes 111C perpendicular to bus bar electrodes 112 and parallel to one another are disposed in central area Ac of solar cell 11. Note that short electrode groups for securing the bonding strength between solar cell 11 and tab lines 20 are disposed between finger electrodes 111C.

Note that in the present embodiment the variations thereof described later, finger electrodes are disposed approximately parallel to one another in a direction crossing a bus bar electrode in a plan view. Accordingly, the finger electrodes have a function of transferring, to the bus bar electrode, electric charges from received light which are generated by solar cell 11.

In the present embodiment and the variations described later, a bus bar electrode crosses finger electrodes at least in central area Ac, and bonded to tab line 20 in central area Ac. Accordingly, the bus bar electrode have a function of transferring electric charges from received light collected by the finger electrodes to tab line 20. The bus bar electrode is defined to include an electrode which is directly connected with the bus bar electrode disposed in central area Ac and crosses a finger electrode in edge area Ap, and exclude an electrode in edge area Ap connected with the bus bar electrode disposed in central area Ac via a line extending in a direction in which a finger electrode is formed.

Here, bus bar electrodes 112 are formed only in central area Ac among edge area Ap and central area Ac. In this case, in edge area Ap, shortest distance Xf between the edge of solar cell 11 and outermost finger electrode 111P is shorter than distance Xb between the edge of solar cell 11 and bus bar electrode 112, in the longitudinal direction of tab line 20. Electrically conductive bonding members 40A are, however, disposed in both edge area Ap and central area Ac. Specifically, bonding lengths in the longitudinal direction of tab lines 20 along which tab lines 20 and bus bar electrodes 112 are bonded together is shorter than the lengths of electrically conductive bonding members 40A in the longitudinal direction. The lengths of bus bar electrodes 112 in the longitudinal direction of tab lines 20 are shorter than the lengths of electrically conductive bonding members 40A in the longitudinal direction. Accordingly, even if electrically conductive bonding members 40A are present in edge area Ap, and also even if solar cell 11 and tab lines 20 repeatedly expand and contract due to temperature cycling, stress applied to tab lines 20 between solar cells can be reduced.

Note that bus bar electrodes 112 are formed only in central area Ac among edge area Ap and central area Ac, but may also be formed in an edge area on a side opposite the edge area Ap. Even in this case, the same advantageous effects as those in the above are achieved.

As illustrated in the plan views in FIG. 11, finger electrodes 111P not directly connected with bus bar electrodes 112 and connection electrodes 113A which connect finger electrodes 111P to finger electrodes 111C are disposed in edge area Ap of solar cell 11. Here, connection electrodes 113A are not in contact with electrically conductive bonding members 40A. Such an arrangement of connection electrodes 113A allows electric charges from received light collected by finger electrodes 111P disposed in edge area Ap where bus bar electrodes 112 are not disposed to be transferred to tab lines 20 via finger electrodes 111C and bus bar electrodes 112. Thus, current collecting efficiency can be improved. Connection electrodes 113A are not in contact with electrically conductive bonding members 40A, and thus the bonding strength between tab lines 20 and solar cell 11 in edge area Ap can be securely made lower than the bonding strength in central area Ac.

With regard to finger electrodes 111C connected with connection electrodes 113A, width W_{111B} of electrode portions 111B between bus bar electrodes 112 and connecting points with connection electrodes 113A is greater than width W_{111C} of other finger electrodes 111C. Electrode portions 111B each transfer electric charges from received light collected by two or more finger electrodes, and thus resistance loss will be high if electrode portions 111B have normal electrode width W_{111C}. To address this, electrode portions 111B have width W_{111B} that is greater than width W_{111C}, and thus current collecting efficiency in and in the vicinity of edge area Ap can be improved.

Furthermore, as illustrated in the plan views in FIG. 11, in edge area Ap of solar cell 11, support electrodes 114A which support tab lines 20 are formed in the endmost portions where electrically conductive bonding members 40A are not disposed, in the longitudinal direction of tab line 20. Here, as illustrated in the cross-sectional view in FIG. 11, the thickness (height) of support electrode 114A may be greater than the thickness of electrically conductive bonding member 40A. Accordingly, as illustrated in the cross-sectional view in FIG. 11, a space is present between electrically conductive bonding member 40A and tab line 20 in edge area Ap, and thus electrically conductive bonding member 40A and tab line 20 are prevented from being in contact. Therefore, deterioration of the shape of tab lines 20 in the edge portion of solar cell 11 can be prevented.

Finger electrodes 111PR are disposed in edge area Ap on the back surface of solar cell 11. Finger electrodes 111PR are outermost finger electrodes among finger electrodes 111P disposed in edge area Ap on the back surface. Note that a plurality of finger electrodes 111PR may be disposed on one or both sides of tab line 20. The spacing between finger electrodes 111PR and the spacing between finger electrode 111PR and another finger electrode may be different from the spacing between finger electrodes 111C and the spacing between finger electrodes 111P.

When finger electrodes 111PR are disposed on the back surface, current collecting efficiency on the back surface increases, yet more light is prevented from entering through the back surface than light prevented from entering through the front surface. However, solar cell 11 according to the present embodiment is a mono-facial element whose light-receiving surface is the front surface. Thus, an increase in current collecting efficiency on the back surface has a greater influence than the influence of an increase in the amount of light prevented from entering through the back surface. Accordingly, solar cell 11 yields more advantageous effects of collecting current.

### [2-2. Configuration of Collector Electrode According to Variation 1 of Embodiment 2]

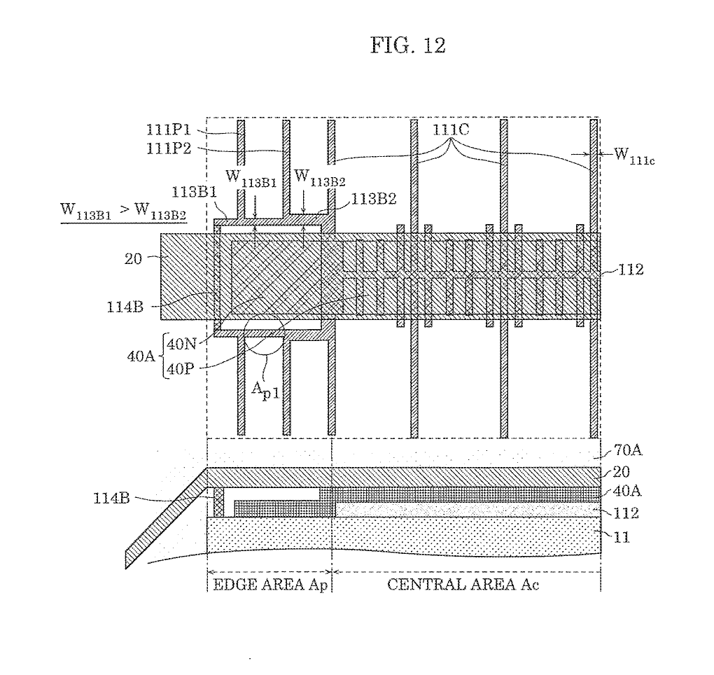

FIG. 12 is a plan view and a cross-sectional view illustrating an electrode configuration of solar cell 11 according to Variation 1 of Embodiment 2. More specifically, FIG. 12 shows an enlarged perspective plan view of the front surface of solar cell 11 in the structural cross-sectional view in FIG. 4, and an enlarged cross-sectional view of a portion around the front surface of solar cell 11. The electrode configuration of solar cell 11 according to this variation is different from the electrode configuration of solar cell 11 illustrated in FIG. 11, only in the configurations of finger electrodes, connection electrodes, and a support electrode in edge area Ap. The following description focuses on differences from the electrode configuration of solar cell 11 illustrated in FIG. 11 while a description of the same points is omitted.

Bus bar electrode 112 is formed only in central area Ac among edge area Ap and central area Ac. In contrast, electrically conductive bonding member 40A is disposed in both edge area Ap and central area Ac. Specifically, a bonding length in the longitudinal direction of tab line 20 along which bus bar electrode 112 and tab line 20 are bonded together is shorter than the length of electrically conductive bonding member 40A in the longitudinal direction. Further, the length of bus bar electrode 112 in the longitudinal direction of tab line 20 is shorter than the length of electrically conductive bonding member 40A in the longitudinal direction. Accordingly, even if solar cell 11 and tab line 20 repeatedly expand and contract due to temperature cycling, stress applied to tab line 20 between solar cells can be reduced.

Note that bus bar electrode 112 is formed only in central area Ac among edge area Ap and central area Ac, but may also be formed in an edge area on a side opposite the edge area Ap. Even in this case, the same advantageous effects as those in the above are achieved.

As illustrated in the plan view in FIG. 12, finger electrodes 111P1 and 111P2 not directly connected with bus bar electrode 112, connection electrode 113B1 which connects finger electrodes 111P1 and 111P2, and connection electrode 113B2 which connects finger electrodes 111P1 and 111P2 to finger electrode 111C are disposed in edge area Ap of solar cell 11. Here, connection electrodes 113B1 and 113B2 are not in contact with electrically conductive bonding member 40A. The arrangement of connection electrodes 113B1 and 113B2 allows electric charges from received light collected by finger electrodes 111P1 and 111P2 disposed in edge area Ap where bus bar electrode 112 is not disposed to be transferred to tab line 20 via finger electrodes 111C and bus bar electrode 112. Thus, current collecting efficiency can be improved. Connection electrodes 113B1 and 113B2 are not in contact with electrically conductive bonding member 40A, and thus bonding strength between tab line 20 and solar cell 11 in edge area Ap can be securely made lower than the bonding strength in central area Ac.

With regard to finger electrode 111C to which connection electrode 113B2 is connected, the width of an electrode portion between bus bar electrode 112 and a connecting point with connection electrode 113B2 is greater than width W_{111C} of other finger electrodes 111C. The electrode portion transfers electric charges from received light collected by three finger electrodes, and thus a resistance loss is high if the electrode portion has normal width W_{111C}. To address this, the electrode portion has a width greater than width W_{111C}, and thus current collecting efficiency in and in the vicinity of edge area Ap can be improved.

Furthermore, width W_{113B2} of connection electrode 113B2 is greater than width W_{113B1} of connection electrode 113B1. In other words, in edge area Ap, the width of the connection electrode closer to central area Ac is greater than the width of the connection electrode farther from central area Ac. Current collecting efficiency in and in the vicinity of edge area Ap is further improved by making the width of connection electrode 113B2, which transfers electric charges from received light collected by two finger electrodes 111P1 and 111P2, greater than the width of connection electrode 113B1 which transfers electric charges from received light collected by single finger electrode 111P1.

As illustrated in the plan view in FIG. 12, in edge area Ap of solar cell 11, support electrode 114B which supports tab line 20 is formed in the outermost portion where electrically conductive bonding member 40A is not disposed in the longitudinal direction of tab line 20. Here, as illustrated in the cross-sectional view in FIG. 12, the thickness (height) of support electrode 114B may be greater than the thickness of electrically conductive bonding member 40A. Accordingly, as illustrated in the cross-sectional view in FIG. 12, a space is present between electrically conductive bonding member 40A and tab line 20 in edge area Ap, and thus electrically conductive bonding member 40A and tab line 20 are prevented from being in contact. Thus, deterioration of the shape of tab line 20 in the edge portion of solar cell 11 can be prevented.

Furthermore, as illustrated in the plan view in FIG. 12, support electrode 114B is electrically connected with connection electrodes 113B1. Accordingly, electric charges collected by outermost finger electrode 111P1 can be transferred to tab line 20 via support electrode 114B and another connection electrode 113B1 disposed across tab line 20 from finger electrode 111P1. Accordingly, for example, a connection electrode formed in area Ap1 on a lower side of tab line 20 can be omitted. Thus, the flexibility of the electrode layout design improves while the current collecting efficiency in and in the vicinity of edge area Ap can be further improved.

### [2-3. Configuration of Collector Electrode According to Variation 2 of Embodiment 2]

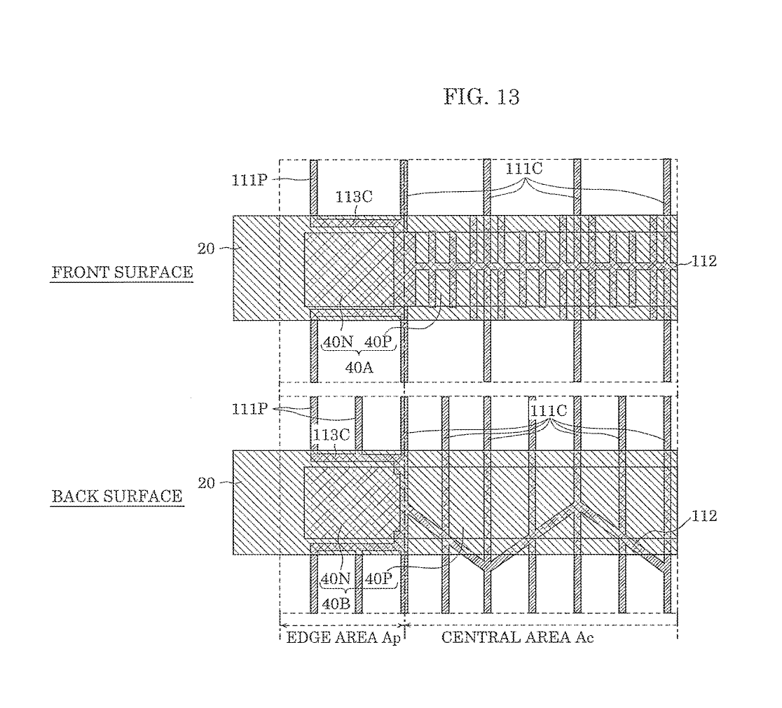

FIG. 13 shows plan views illustrating an electrode configuration of solar cell 11 according to Variation 2 of Embodiment 2 on a front surface side and a back surface side. More specifically, FIG. 13 shows enlarged perspective plan views of the front surface and the back surface of solar cell 11 in the structural cross-sectional view in FIG. 4. The electrode configuration of solar cell 11 according to this variation is different from the electrode configuration of solar cell 11 illustrated in FIG. 11, only in the configurations of finger electrodes, connection electrodes, and support electrodes in edge area Ap. The following description focuses on differences from the electrode configuration of solar cell 11 illustrated in FIG. 11 while a description of the same points is omitted.

Bus bar electrodes 112 are formed only in central area Ac among edge area Ap and central area Ac. In contrast, electrically conductive bonding members 40A and 40B are disposed in both edge area Ap and central area Ac. In other words, the bonding lengths in the longitudinal direction of tab lines 20 along which tab lines 20 and bus bar electrodes 112 are bonded together are shorter than the lengths of electrically conductive bonding members 40A and 40B in the longitudinal direction. The lengths of bus bar electrodes 112 in the longitudinal direction of tab lines 20 are shorter than the lengths of electrically conductive bonding members 40A and 40B in the longitudinal direction. Accordingly, even if solar cell 11 and tab lines 20 repeatedly expand and contract due to temperature cycling, stress applied to tab lines 20 between solar cells can be reduced.

Note that bus bar electrodes 112 are formed only in central area Ac among edge area Ap and central area Ac, but may also be formed in the edge area on a side opposite the edge area Ap. Even in this case, the same advantageous effects as those in the above can be achieved.

As illustrated in FIG. 13, finger electrodes 111P not directly connected with bus bar electrodes 112 and connection electrodes 113C which connect finger electrodes 111P to finger electrodes 111C are disposed in edge area Ap of solar cell 11. Here, connection electrodes 113C are not in contact with electrically conductive bonding members 40A and 40B, and covered with tab lines 20 in the plan views. The arrangement of connection electrodes 113C allows electric charges from received light collected by finger electrodes 111P disposed in edge area Ap where bus bar electrodes 112 are not disposed to be transferred to tab lines 20 via finger electrodes 111C and bus bar electrodes 112. Thus, current collecting efficiency can be improved. In addition, connection electrodes 113C are covered with tab lines 20 in the plan views, and thus less light is prevented from entering due to the connection electrodes, and current collecting efficiency can be further improved. Connection electrodes 113C are not in contact with electrically conductive bonding members 40A and 40B, and thus the bonding strength between tab lines 20 and solar cell 11 in edge area Ap can be securely made lower than the bonding strength in central area Ac.

With regard to finger electrodes 111C to which connection electrodes 113C are connected, the widths of electrode portions between bus bar electrodes 112 and connecting points with connection electrodes 113C are greater than the width of other finger electrodes 111C. The electrode portions transfers electric charges from received light collected by two or more finger electrodes, and thus resistance of collecting current will be high if the electrode portions have a normal width. To address this, the electrode portions have widths greater than the normal width, and thus the current collecting efficiency in and in the vicinity of edge area Ap can be improved.

Note that although not illustrated in FIG. 13, support electrodes which support tab lines 20 may be disposed in edge area Ap in the outermost portions where electrically conductive bonding members 40A and 40B are not disposed in the longitudinal direction of tab line 20. Furthermore, the support electrodes may be electrically connected with connection electrodes 113C.

### [2-4. Configuration of Collector Electrode According to Variation 3 of Embodiment 2]

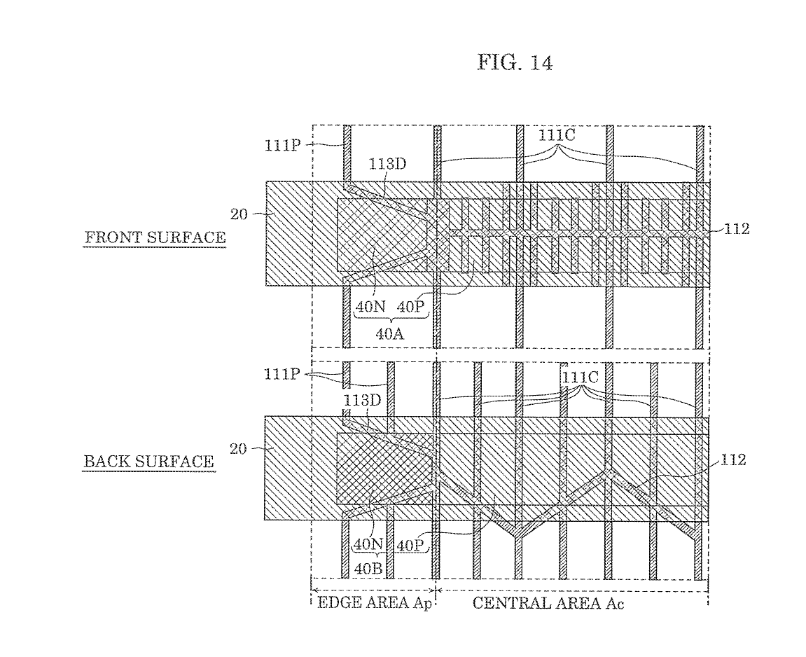

FIG. 14 shows plan views illustrating an electrode configuration of solar cell 11 according to Variation 3 of Embodiment 2 on a front surface side and a back surface side. More specifically, FIG. 14 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 2 illustrated in FIG. 13, only in the configuration of connection electrodes in edge area Ap. The following description focuses on differences from the electrode configuration of solar cell 11 illustrated in FIG. 13 while a description of the same points is omitted.

Bus bar electrodes 112 are formed only in central area Ac among edge area Ap and central area Ac. In contrast, electrically conductive bonding members 40A and 40B are disposed in both edge area Ap and central area Ac. Specifically, the bonding lengths in the longitudinal direction of tab lines 20 along which tab lines 20 and bus bar electrodes 112 are bonded together are shorter than the lengths of electrically conductive bonding members 40A and 40B in the longitudinal direction. The lengths of bus bar electrodes 112 in the longitudinal direction of tab lines 20 are shorter than the lengths of electrically conductive bonding members 40A and 40B in the longitudinal direction. Accordingly, even if solar cell 11 and tab lines 20 repeatedly expand and contract due to temperature cycling, stress applied to tab lines 20 between solar cells can be reduced.

Note that bus bar electrodes 112 are formed only in central area Ac among edge area Ap and central area Ac, but may also be formed in an edge area on a side opposite edge area Ap. Even in this case, the same advantageous effects as those in the above can be achieved.

As illustrated in FIG. 14, finger electrodes 111P not directly connected with bus bar electrodes 112, connection electrodes 113D which connect finger electrodes 111P to finger electrodes 111C are disposed in edge area Ap of solar cell 11. The arrangement of connection electrodes 113D allows electric charges from received light collected by finger electrodes 111P disposed in edge area Ap where bus bar electrodes 112 are not disposed to be transferred to tab lines 20 via finger electrodes 111C and bus bar electrodes 112. Thus, current collecting efficiency can be improved.

Connection electrodes 113D are in contact with electrically conductive bonding members 40A and 40B in edge area Ap on a side closer to central area Ac, and are not in contact with electrically conductive bonding members 40A and 40B in edge area Ap on a side farther from central area Ac. Stated differently, connection electrodes 113D each have, in edge area Ap, a portion separate from electrically conductive bonding member 40A/40B. Accordingly, the bonding strength between solar cell 11 and tab lines 20 in edge area Ap can be securely made lower than the bonding strength in central area Ac.

Connection electrodes 113D are covered with tab lines 20 in the plan views. Accordingly, less light is prevented from entering due to connection electrodes 113D, and light collecting efficiency can be further improved.

Note that although not illustrated in FIG. 14, support electrodes which support tab lines 20 may be disposed in edge area Ap in the outermost portions where electrically conductive bonding members 40A and 40B are not disposed in the longitudinal direction of tab lines 20. The support electrodes may be electrically connected with connection electrodes 113D.

### [2-5. Configuration of Collector Electrode According to Variation 4 of Embodiment 2]

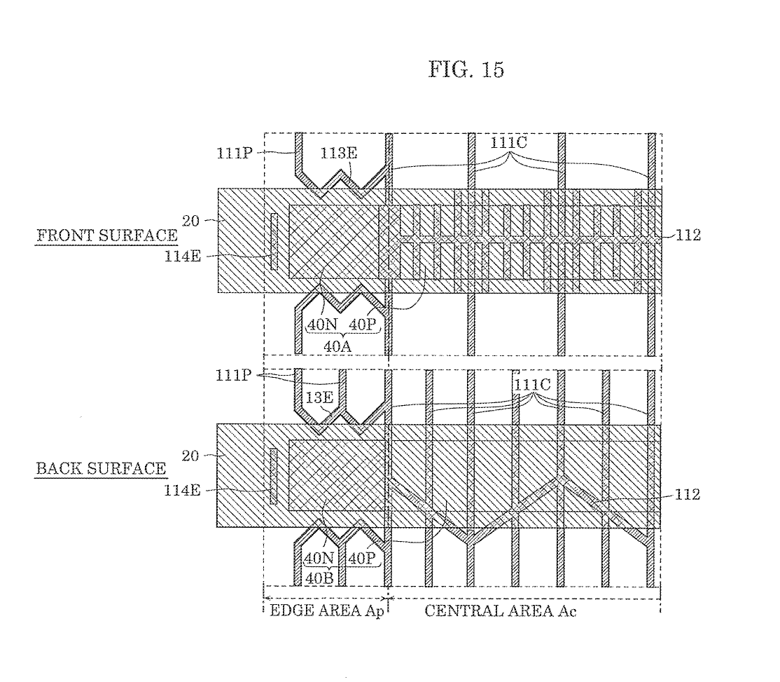

FIG. 15 shows plan views illustrating an electrode configuration of solar cell 11 according to Variation 4 of Embodiment 2 on a front surface side and a back surface side. More specifically, FIG. 15 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 2 illustrated in FIG. 13 only in the configuration of connection electrodes and support electrodes in edge area Ap. The following description focuses on differences from the electrode configuration of solar cell 11 illustrated in FIG. 13 while a description of the same points is omitted.

Bus bar electrodes 112 are formed only in central area Ac among edge area Ap and central area Ac. In contrast, electrically conductive bonding members 40A and 40B are disposed in both edge area Ap and central area Ac. In other words, bonding lengths in the longitudinal direction of tab lines 20 along which tab lines 20 and bus bar electrodes 112 are bonded together are shorter than the lengths of electrically conductive bonding members 40A and 40B in the longitudinal direction. The lengths of bus bar electrodes 112 in the longitudinal direction of tab lines 20 are shorter than the lengths of electrically conductive bonding members 40A and 40B in the longitudinal direction. Accordingly, even if solar cell 11 and tab lines 20 repeatedly expand and contract due to temperature cycling, stress applied to tab lines 20 between solar cells can be reduced.

Note that bus bar electrodes 112 are formed only in central area Ac among edge area Ap and central area Ac, but may also be formed in the edge area on a side opposite edge area Ap. Even in this case, the same advantageous effects as in the above can be achieved.

As illustrated in FIG. 15, finger electrodes 111P not directly connected with bus bar electrodes 112, and connection electrodes 113E which connect finger electrodes 111P to finger electrodes 111C are disposed in edge area Ap of solar cell 11. The arrangement of connection electrodes 113E allows electric charges from received light collected by finger electrodes 111P disposed in edge area Ap where bus bar electrodes 112 are not disposed to be transferred to tab lines 20 via finger electrodes 111C and bus bar electrodes 112. Thus, current collecting efficiency can be improved.

In the plan views, connection electrodes 113E are formed into zigzags relative to the longitudinal direction of tab lines 20 between finger electrodes 111C and 111P, and discretely covered with tab lines 20. Accordingly, less light is prevented from entering due to connection electrodes 113E, and light collecting efficiency can be further improved.

Connection electrodes 113E are not in contact with electrically conductive bonding members 40A and 40B. Accordingly, the bonding strength between solar cell 11 and tab lines 20 in edge area Ap can be securely made lower than the bonding strength in central area Ac.

In edge area Ap, support electrodes 114E which support tab lines 20 are formed in the outermost portions where electrically conductive bonding members 40A and 40B are not disposed in the longitudinal direction of tab line 20. Here, the thickness (height) of support electrodes 114E may be greater than the thickness of electrically conductive bonding members 40A and 40B. This provides, in edge area Ap, a space between tab line 20 and electrically conductive bonding member 40A, and a space between tab line 20 and electrically conductive bonding member 40B. Accordingly, electrically conductive bonding members 40A and 40B are prevented from being in contact with tab lines 20. Thus, deterioration of the shape of tab lines 20 in the edge portion of solar cell 11 can be prevented.

Note that support electrodes 114E may be electrically connected with connection electrodes 113E. Accordingly, for example, electric charges collected by outermost finger electrode 111P on the back surface can be transferred to tab line 20 via support electrode 114E and connection electrode 113E disposed across tab line 20 from outermost finger electrode 111P. Accordingly, for example, in edge area Ap on the back surface, a portion of connection electrode 113E directly connected with outermost finger electrode 111P can be omitted. Thus, the current collecting efficiency in and in the vicinity of edge area Ap can be further improved, and also flexibility in designing the electrode layout improves.

### [2-6. Configuration of Collector Electrode According to Variation 5 of Embodiment 2]

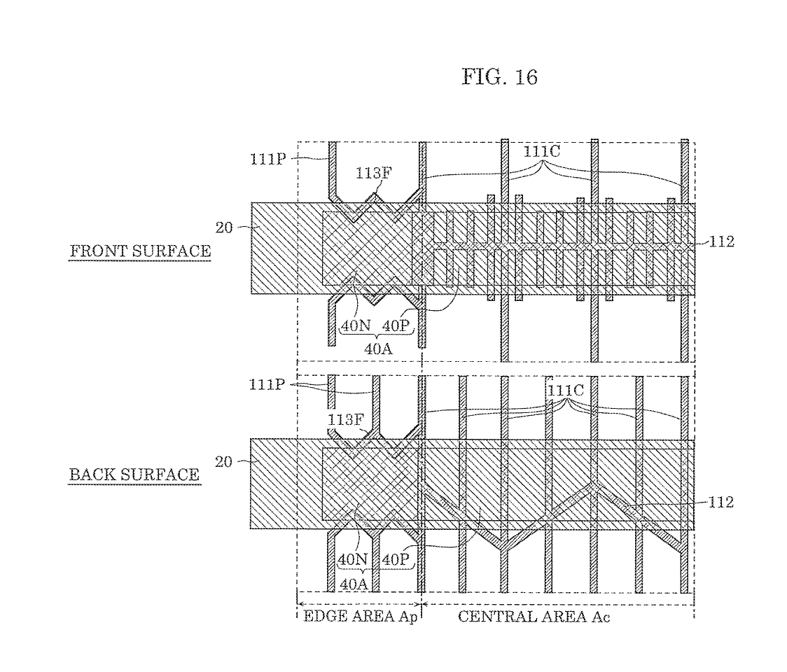

FIG. 16 shows plan views illustrating an electrode configuration of solar cell 11 according to Variation 5 of Embodiment 2 on a front surface side and a back surface side. More specifically, FIG. 16 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 2 illustrated in FIG. 13 only in the configuration of connection electrodes in edge area Ap. The following description focuses on differences from the electrode configuration of solar cell 11 illustrated in FIG. 13 while a description of the same points is omitted.

Bus bar electrodes 112 are formed only in central area Ac among edge area Ap and central area Ac. In contrast, electrically conductive bonding members 40A and 40B are disposed in both edge area Ap and central area Ac. Thus, the bonding lengths in the longitudinal direction of tab lines 20 along which tab lines 20 and bus bar electrodes 112 are bonded together are shorter than the lengths of electrically conductive bonding members 40A and 40B in the longitudinal direction. The lengths of bus bar electrodes 112 in the longitudinal direction of tab lines 20 are shorter than the lengths of electrically conductive bonding members 40A and 40B in the longitudinal direction. Accordingly, even if solar cell 11 and tab lines 20 repeatedly expand and contract due to temperature cycling, stress applied to tab lines 20 between solar cells can be reduced.

Note that bus bar electrodes 112 are formed only in central area Ac among edge area Ap and central area Ac, but may also be formed in an edge area located on a side opposite edge area Ap. Even in this case, the same advantageous effects as those in the above are achieved.

As illustrated in FIG. 16, finger electrodes 111P not directly connected with bus bar electrodes 112, and connection electrodes 113F which connect finger electrodes 111P to finger electrodes 111C are disposed in edge area Ap of solar cell 11. The arrangement of connection electrodes 113F allows electric charges from received light collected by finger electrodes 111P disposed in edge area Ap where bus bar electrodes 112 are not disposed to be transferred to tab lines 20 via finger electrodes 111C and bus bar electrodes 112. Thus, current collecting efficiency can be improved.

In the plan views, connection electrodes 113F are formed into zigzags between finger electrodes 111C and 111P relative to the longitudinal direction of tab lines 20, and are discretely covered with tab lines 20. Accordingly, less light is prevented from entering due to connection electrodes 113F, and light collecting efficiency can be further improved.

Connection electrodes 113F are discretely in contact with electrically conductive bonding members 40A and 40B. Accordingly, the bonding strength between solar cell 11 and tab lines 20 in edge area Ap can be securely made lower than the bonding strength in central area Ac.

Note that although not illustrated in FIG. 16, support electrodes which support tab lines 20 may be disposed in edge area Ap in the outermost portions where electrically conductive bonding members 40A and 40B are not disposed in the longitudinal direction of tab line 20. The support electrodes may be electrically connected with connection electrodes 113F.

### [2-7. Configuration of Collector Electrode According to Variation 6 of Embodiment 2]

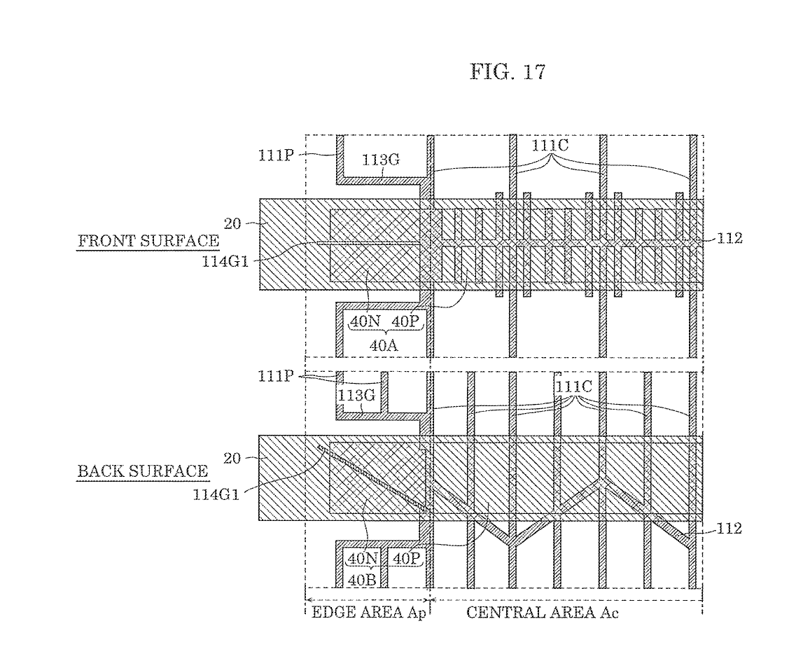

FIG. 17 shows plan views illustrating an electrode configuration of solar cell 11 according to Variation 6 of Embodiment 2 on a front surface side and a back surface side. More specifically, FIG. 17 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 2 illustrated in FIG. 13 in the configuration of connection electrodes in edge area Ap and in that dummy electrodes are disposed in edge area Ap. The following description focuses on differences from the electrode configuration of solar cell 11 illustrated in FIG. 13 while a description of the same points is omitted.

Bus bar electrodes 112 are formed only in central area Ac among edge area Ap and central area Ac. In contrast, electrically conductive bonding members 40A and 40B are disposed in both edge area Ap and central area Ac. Thus, bonding lengths in the longitudinal direction of tab lines 20 along which tab lines 20 and bus bar electrodes 112 are bonded together are shorter than the lengths of electrically conductive bonding members 40A and 40B in the longitudinal direction. The lengths of bus bar electrodes 112 in the longitudinal direction of tab lines 20 are shorter than the lengths of electrically conductive bonding members 40A and 40B in the longitudinal direction. Accordingly, even if solar cell 11 and tab lines 20 repeatedly expand and contract due to temperature cycling, stress applied to tab lines 20 between solar cells can be reduced.

Note that bus bar electrodes 112 are formed only in central area Ac among edge area Ap and central area Ac, but may also be formed in an edge area on a side opposite edge area Ap. Even in this case, the same advantageous effects as those in the above are achieved.

As illustrated in FIG. 17, finger electrodes 111P not directly connected with bus bar electrodes 112, and connection electrodes 113G which connect finger electrodes 111P to finger electrodes 111C are disposed in edge area Ap of solar cell 11. The arrangement of connection electrodes 113G allows electric charges from received light collected by finger electrodes 111P disposed in edge area Ap where bus bar electrodes 112 are not disposed to be transferred to tab lines 20 via finger electrodes 111C and bus bar electrodes 112. Thus, current collecting efficiency can be improved.

Connection electrodes 113G are not in contact with electrically conductive bonding members 40A and 40B, and are not covered with tab lines 20 in the plan views. Furthermore, solar cell 11 according to this variation includes dummy electrodes 114G1 in edge area Ap. Here, the surface area occupancy in the plan views of dummy electrodes 114G1 relative to electrically conductive bonding members 40A and 40B in edge area Ap is lower than the surface area occupancy in the plan views of bus bar electrodes 112 relative to electrically conductive bonding members 40A and 40B in central area Ac. In order to achieve this relation, for example, the widths of dummy electrodes 114G1 are narrower than the widths of bus bar electrodes 112. The arrangement of dummy electrodes 114G1 allows tab lines 20 in edge area Ap to be bonded onto solar cell 11 only on dummy electrodes 114G1. Thus, the bonding strength between solar cell 11 and tab lines 20 in edge area Ap can be securely made lower than the bonding strength in central area Ac. Accordingly, even if solar cell 11 and tab lines 20 repeatedly expand and contract due to temperature cycling, stress applied to tab lines 20 between solar cells can be reduced.

Note that dummy electrode 11401 may extend parallel to the direction in which tab line 20 is formed (on the front surface in FIG. 17), or may be formed inclined to the direction in which tab line 20 is formed (on the back surface in FIG. 17).

Note that although not illustrated in FIG. 17, support electrodes which support tab lines 20 may be disposed in edge area Ap in the outermost portions where electrically conductive bonding members 40A and 40B are not disposed in the longitudinal direction of tab line 20. The support electrodes may be electrically connected with connection electrodes 113G.

### [2-8. Configuration of Collector Electrode According to Variation 7 of Embodiment 2]

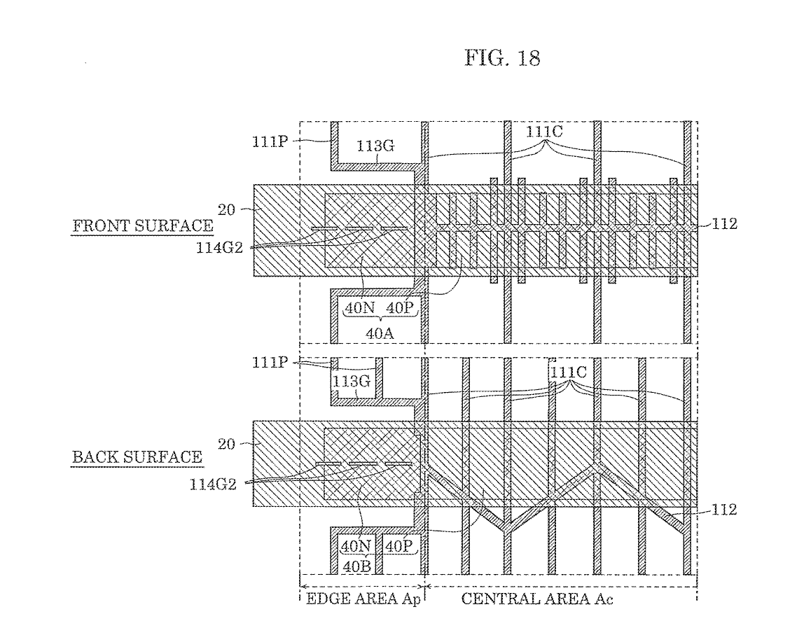

FIG. 18 shows plan views illustrating an electrode configuration of solar cell 11 according to Variation 7 of Embodiment 2 on a front surface side and a back surface side. More specifically, FIG. 18 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 6 illustrated in FIG. 17 only in the configuration of dummy electrodes in edge area Ap. The following description focuses on differences from the electrode configuration of solar cell 11 illustrated in FIG. 17 while a description of the same points is omitted.

Solar cell 11 according to this variation includes dummy electrodes 114G2 in edge area Ap. Here, the surface area occupancy in the plan views of dummy electrodes 114G2 relative to electrically conductive bonding members 40A and 40B in edge area Ap is lower than the surface area occupancy in the plan views of bus bar electrodes 112 relative to electrically conductive bonding members 40A and 40B in central area Ac. In order to achieve this relation, for example, the widths of dummy electrodes 114G2 are narrower than the widths of bus bar electrodes 112. Furthermore, dummy electrodes 114G2 are discretely disposed in edge area Ap, and discretely bonded by electrically conductive bonding members 40A and 40B. The arrangement of dummy electrodes 114G2 allows tab lines 20 to be bonded onto solar cell 11 in edge area Ap only on dummy electrodes 114G2. Thus, the bonding strength between solar cell 11 and tab lines 20 in edge area Ap can be securely made lower than the bonding strength in central area Ac. Accordingly, even if solar cell 11 and tab lines 20 repeatedly expand and contract due to temperature cycling, stress applied to tab lines 20 between solar cells can be reduced.

Note that dummy electrodes 114G2 may extend parallel to the direction in which tab lines 20 are formed, or may be formed inclined relative to the direction in which tab lines 20 are formed.

### [2-9. Configuration of Collector Electrode According to Variation 8 of Embodiment 2]

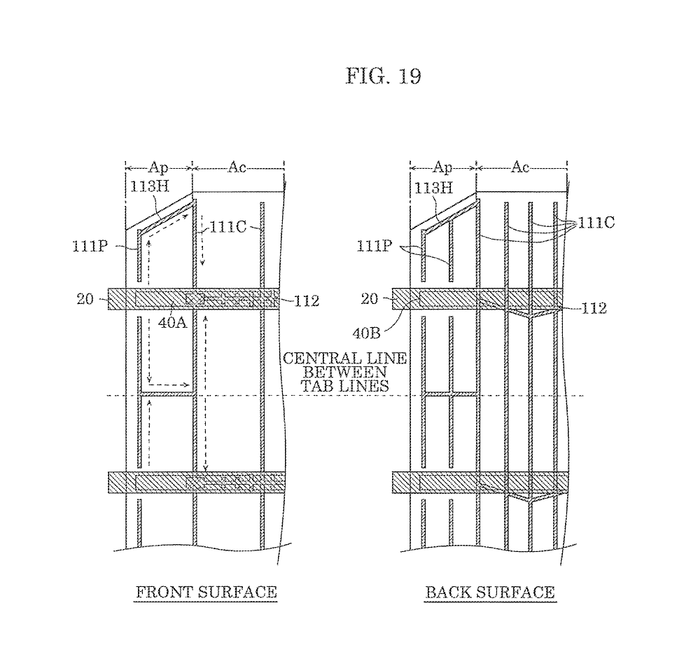

FIG. 19 shows plan views illustrating an electrode configuration of solar cell 11 according to Variation 8 of Embodiment 2 on a front surface side and a back surface side. More specifically, FIG. 19 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 2 illustrated in FIG. 13 in the configuration of connection electrodes in edge area Ap. The following description focuses on differences from the electrode configuration of solar cell 11 illustrated in FIG. 13 while a description of the same points is omitted.

As illustrated in FIG. 19, finger electrodes 111P not directly connected with bus bar electrodes 112, and connection electrodes 113H which connect finger electrodes 111P to finger electrodes 111C are disposed in edge area Ap of solar cell 11. The arrangement of connection electrodes 113H allows electric charges from received light collected by finger electrodes 111P disposed in edge area Ap where bus bar electrodes 112 are not disposed to be transferred to tab lines 20 via finger electrodes 111C and bus bar electrodes 112. Thus, current collecting efficiency can be improved.

Connection electrodes 113H are disposed in the outer edge areas of the flat areas of the solar cell. Specifically, connection electrodes 113H are formed in inactive areas that do not have a light collecting function. This prevents an increase in the amount of light prevented from entering due to the arrangement of connection electrodes 113H.

Connection electrodes 113H are not in contact with electrically conductive bonding members 40A and 40B, and are not covered with tab lines 20 in the plan views. Accordingly, the bonding strength between solar cell 11 and tab lines 20 in edge area Ap can be securely made lower than the bonding strength in central area Ac.

Note that although not illustrated in FIG. 19, support electrodes which support tab lines 20 may be disposed in edge area Ap in the outermost portions where electrically conductive bonding members 40A and 40B are not disposed in the longitudinal direction of tab lines 20.

The widths of finger electrodes 111C connected with connection electrodes 113H may be the greatest among the widths of other finger electrodes 111C. Finger electrodes 111C connected with connection electrodes 113H transfer electric charges from received light collected by finger electrodes 111P, in addition to electric charges from received light collected by finger electrodes 111C connected with connection electrodes 113H, and thus resistance loss will be greater if the finger electrodes have the normal width. To address this, if the widths of finger electrodes 111C connected with connection electrodes 113H are made greater, the current collecting efficiency in and in the vicinity of edge area Ap can be improved.

Furthermore, the widths of connection electrodes 113H may be increased toward central area Ac. For example, if on the back surface, the width of a portion of connection electrode 113H closer to central area Ac which transfers electric charges from received light collected by two finger electrodes 111P is made greater than the width of a portion of connection electrode 113H farther from central area Ac, which transfers electric charges from received light collected by one finger electrode 111P, current collecting efficiency in and in the vicinity of edge area Ap can be further improved.

### [2-10. Configuration of Collector Electrode According to Variation 9 of Embodiment 2]

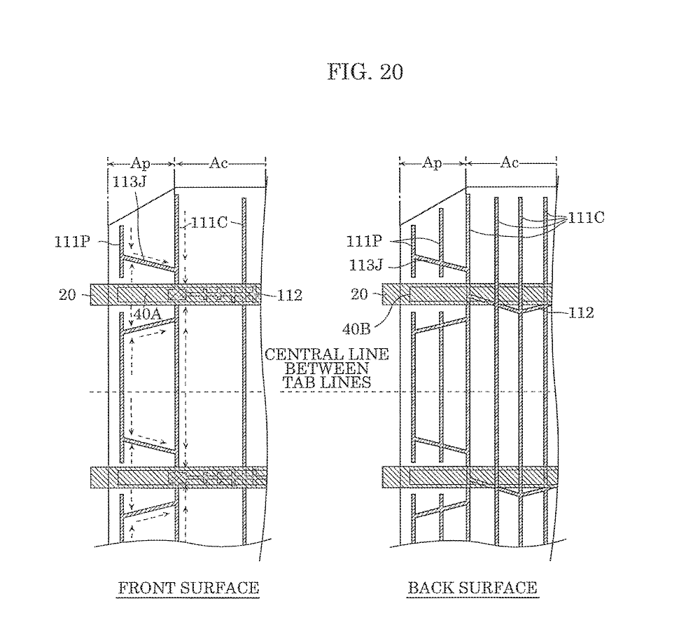

FIG. 20 shows plan views illustrating an electrode configuration of solar cell 11 according to Variation 9 of Embodiment 2 on a front surface side and a back surface side. More specifically, FIG. 20 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 8 illustrated in FIG. 19 in the configuration of a connection electrode in edge area Ap. The following description focuses on differences from the electrode configuration of solar cell 11 illustrated in FIG. 19 while a description of the same points is omitted.

As illustrated in FIG. 20, finger electrodes 111P not directly connected with bus bar electrodes 112, and connection electrodes 113J which connect finger electrodes 111P to finger electrodes 111C are disposed in edge area Ap of solar cell 11. The arrangement of connection electrodes 113J allows electric charges from received light collected by finger electrodes 111P disposed in edge area Ap where bus bar electrodes 112 are not disposed to be transferred to tab lines 20 via finger electrodes 111C and bus bar electrodes 112. Thus, current collecting efficiency can be improved.

Connection electrodes 113J are not in contact with electrically conductive bonding members 40A and 40B, and are not covered with tab lines 20 in the plan views. Accordingly, the bonding strength between solar cell 11 and tab lines 20 in edge area Ap can be securely made lower than the bonding strength in central area Ac.

Connection electrodes 113J are disposed in active areas having a light collecting function, and disposed close to tab lines 20, within flat areas of a solar cell. Accordingly, as compared with connection electrodes 113H illustrated in FIG. 19, more light is prevented from entering due to the arrangement of connection electrodes 113J, yet the resistance loss caused when transferring electric charges from received light to bus bar electrodes 112 can be reduced.

The widths of finger electrodes 111C connected with connection electrodes 113J may be the greatest among the widths of other finger electrodes 111C. Finger electrodes 111C connected with connection electrodes 113J also transfer electric charges from received light collected by finger electrodes 111P, in addition to the electric charges from received light collected by finger electrodes 111C connected with connection electrodes 113J, and thus resistance loss increases if the finger electrodes have a normal electrode width. To address this, current collecting efficiency in and in the vicinity of edge area Ap can be improved by giving great widths to finger electrodes 111C connected with connection electrodes 113J.

Furthermore, the widths of connection electrodes 113J may be increased toward central area Ac. For example, if on the back surface, the width of a portion of connection electrode 113J closer to central area Ac, which transfers electric charges from received light collected by two finger electrodes 111P, is made greater than the width of a portion of connection electrode 113J farther from central area Ac, which transfers electric charges from received light collected by single finger electrode 111P, current collecting efficiency in and in the vicinity of edge area Ap can be further improved.

### [2-11. Configuration of Collector Electrode According to Variation 10 of Embodiment 2]

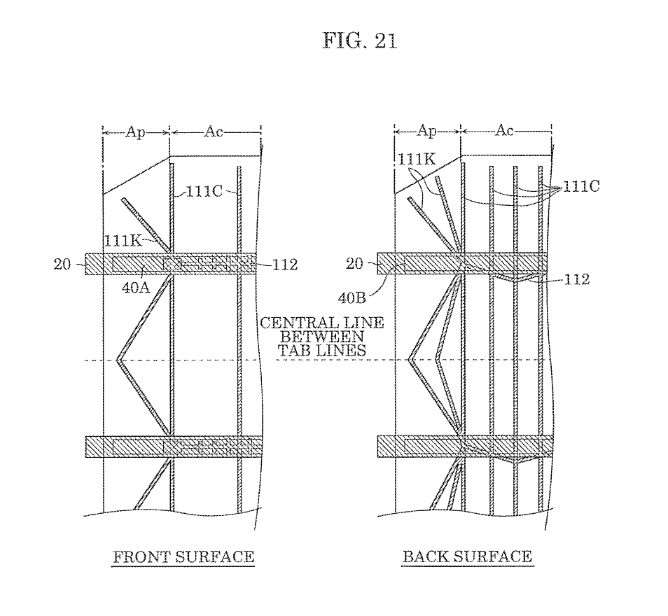

FIG. 21 shows plan views illustrating an electrode configuration of solar cell 11 according to Variation 10 of Embodiment 2 on a front surface side and a back surface side. More specifically, FIG. 21 shows enlarged perspective plan views of the front surface and the back surface of solar cell 11 in the structural cross-sectional view in FIG. 4. The electrode configuration of solar cell 11 according to this variation is different from the electrode configuration of solar cell 11 according to Variation 8 illustrated in FIG. 19 in the configuration of finger electrodes and connection electrodes in edge area Ap. The following description focuses on differences from the electrode configuration of solar cell 11 illustrated in FIG. 19 while a description of the same points is omitted.

As illustrated in FIG. 21, finger electrodes 111K which are directly connected with finger electrodes 111C disposed in central area Ac, and are not parallel to finger electrodes 111C are disposed in edge area Ap of solar cell 11. Since finger electrodes 111C and finger electrodes 111K are connected directly, connection electrodes are not disposed.

According to the arrangement of finger electrodes 111K, the surface area of electrodes in an active area can be reduced as compared with the case where a connection electrode which connects finger electrodes is disposed, and thus less light is prevented from entering. Thus, light collecting efficiency can be improved.

### [2-12. Configuration of Collector Electrode According to Variation 11 of Embodiment 2]

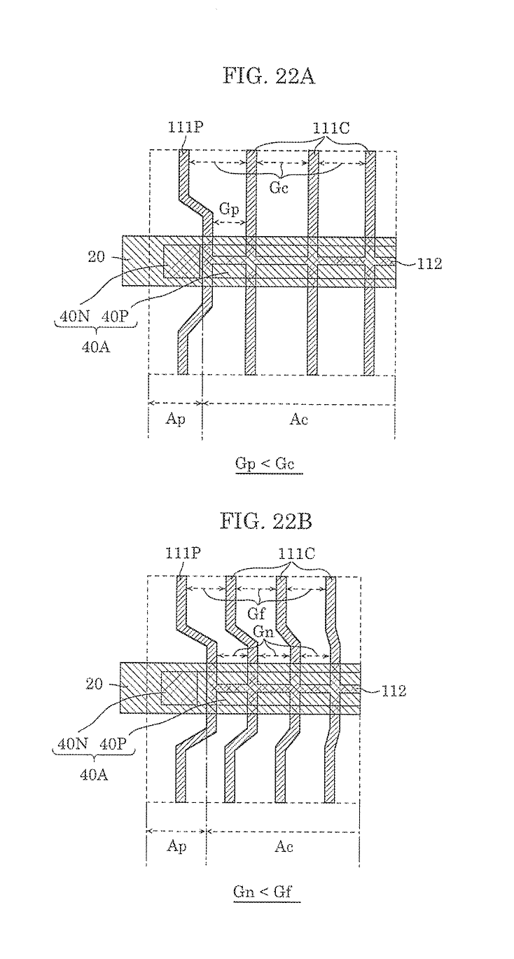

FIG. 22A is a plan view illustrating an electrode configuration of solar cell 11 according to Variation 11 of Embodiment 2. More specifically, FIG. 22A shows an enlarged perspective plan view of the front surface of solar cell 11 in the structural cross-sectional view in FIG. 4. The electrode configuration of solar cell 11 according to this variation is different from the electrode configuration of solar cell 11 according to Variation 2 illustrated in FIG. 11 in the spacing between finger electrodes as a configuration. The following description focuses on differences from the electrode configuration of solar cell 11 illustrated in FIG. 11 while a description of the same points is omitted.

As illustrated in the plan view in FIG. 22A, finger electrode 111P connected with bus bar electrode 112 is disposed in edge area Ap of solar cell 11. Here, with regard to the spacing between finger electrode 111P which crosses the endmost portion of bus bar electrode 112 and finger electrode 111C next to finger electrode 111P, such spacing Gc in a first area farther from bus bar electrode 112 is greater than such spacing Gp in a second area closer to bus bar electrode 112 than the first area is. Accordingly, finger electrode 111P can be disposed also in edge area Ap while the length of bus bar electrode 112 is shorter than the length of electrically conductive bonding member 40A/40B.

### [2-13. Configuration of Collector Electrode According to Variation 12 of Embodiment 2]

FIG. 22B is a plan view illustrating an electrode configuration of solar cell 11 according to Variation 12 of Embodiment 2. More specifically, FIG. 22B shows an enlarged perspective plan view of the front surface of solar cell 11 in the structural cross-sectional view in FIG. 4. The electrode configuration of solar cell 11 according to this variation is different from the electrode configuration of solar cell 11 according to Variation 11 illustrated in FIG. 22A in the spacing between finger electrodes. The following description focuses on differences from the electrode configuration of solar cell 11 illustrated in FIG. 22A while a description of the same points is omitted.

As illustrated in the plan view in FIG. 22B, finger electrode 111P connected with bus bar electrode 112 is disposed in edge area Ap of solar cell 11. Here, in the plan view, spacing Gf between finger electrodes in a first area farther from bus bar electrode 112 is greater than spacing Gn between finger electrodes in a second area closer to bus bar electrode 112 than the first area is. Accordingly, finger electrode 111P can be disposed also in edge area Ap while the length of bus bar electrode 112 is shorter than the length of electrically conductive bonding member 40A/40B. Thus, current collecting efficiency can be improved while reducing stress applied to tab line 20.

### Other Embodiments

The above completes description of the solar cell module to according to the present disclosure based on Embodiments 1 and 2 and the variations thereof, yet the present disclosure is not limited to Embodiments 1 and 2 and the variations thereof described above.

For example, in Embodiments 1 and 2 and the variations thereof described above, it is sufficient if solar cell 11 has a function of providing photovoltaic effects, and thus the structure of the solar cell is not limited to those as described above.

Embodiments 1 and 2 and the variations thereof described above have shown aspects in which both the front surface and the back surface of solar cell 11 have an electrode configuration having the features as described above, yet one of the surfaces of solar cell 11 may have the electrode configuration having the above features.

Specifically, a solar cell module includes: two solar cells 11 adjacent to each other in a direction parallel to a light-receiving surface of the solar cell module; tab line 20 which is disposed on a front surface of a first solar cell among two solar cells 11 and a back surface of a second solar cell among two solar cells 11, and electrically connects two solar cells 11; and electrically conductive bonding members 40A and 40B which bond tab line 20 to two solar cells 11, wherein bonding strength between tab line 20 and at least one of two solar cells 11 in edge area Ap is lower than bonding strength between tab line 20 and the at least one of two solar cells 11 in central area Ac. Accordingly, even if solar cell 11 and tab line 20 repeatedly expand and contract due to temperature cycling, stress applied to tab line 20 between solar cells can be reduced.

Furthermore, the bus bar electrodes, the finger electrodes, and the connection electrodes may be formed into curves, rather than straight lines. A connecting portion between a finger electrode and a connection electrode may be roundish in a plan view.

Although the solar cell module according to the above embodiments has a configuration in which solar cells 11 are disposed in a matrix on a plane, but solar cells 11 may not be disposed in a matrix. For example, solar cells 11 may be disposed in a circle or a one-dimensionally straight or curved line.

The scope of the present disclosure may also include embodiments as a result of adding various modifications, which may be conceived by those skilled in the art, to Embodiments 1 and 2 and the variations thereof described above, and embodiments obtained by combining elements and functions in Embodiments 1 and 2 and the variations thereof in any manner as long as the combination does not depart from the spirit of the present disclosure.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module, comprising:
two solar cells adjacent to each other in a direction parallel to a light-receiving surface of the solar cell module;
a tab line which is disposed on a front surface of a first solar cell among the two solar cells and a back surface of a second solar cell among the two solar cells, and electrically connects the two solar cells; and
bonding members which bond the tab line to the two solar cells, wherein
bonding strength between the tab line and at least one of the two solar cells in a first edge area on a side electrically connected with the other of the two solar cells by the tab line is lower than bonding strength between the tab line and the at least one of the two solar cells in a central area.

2. The solar cell module according to claim 1, wherein
the first solar cell includes a bus bar electrode on the front surface and the second solar cell includes a bus bar electrode on the back surface, the bus bar electrodes extending in a longitudinal direction of the tab line and being configured to transfer electric charges from received light to the tab line,
the bonding members bond the tab line to the two solar cells by bonding the tab line to the bus bar electrode included in the first solar cell and bonding the tab line to the bus bar electrode included in the second solar cell, and
on at least one of the front surface of the first solar cell and the back surface of the second solar cell, a length of the bonding member in the longitudinal direction of the tab line is shorter than a length of the bus bar electrode in the longitudinal direction of the tab line.

3. The solar cell module according to claim 2, wherein
in each of the two solar cells, the bus bar electrode is disposed in the central area and a perimeter area, and
a resistance per unit length of the bus bar electrode in the first edge area is lower than a resistance per unit length of the bus bar electrode in the central area.

4. The solar cell module according to claim 3, wherein
in the first edge area in at least one of the two solar cells, a resistance per unit length of a portion of the bus bar electrode closer to the central area is lower than a resistance per unit length of a portion of the bus bar electrode farther from the central area.

5. The solar cell module according to claim 4, wherein
in the at least one of the two solar cells, the bus bar electrode in the first edge area has an inversely tapered shape gradually wider toward the central area in a plan view.

6. The solar cell module according to claim 1, wherein
on each of the front surface and a back surface of the first solar cell and on each of a front surface and the back surface of the second solar cell, the two solar cells each include:
a bus bar electrode which extends in a longitudinal direction of the tab line, and transfers electric charges from received light to the tab line; and
finger electrodes which cross the bus bar electrode in a plan view, and collect electric charges from received light, and
in each of the two solar cells, the bus bar electrode on the back surface extends at least through the central area to reach a point in the first edge area farther from the central area than a point in the first edge area on the front surface that the bus bar electrode on the front surface reaches is, and
among the finger electrodes on the back surface, a finger electrode in the first edge area on the back surface is closer to an edge of the solar cell than an outermost finger electrode in the first edge area on the front surface is, among the finger electrodes on the front surface.

7. The solar cell module according to claim 1, wherein
the first solar cell includes a bus bar electrode on the front surface, and the second solar cell includes a bus bar electrode on the back surface, the bus bar electrodes extending in a longitudinal direction of the tab line and being configured to transfer electric charges from received light to the tab line,
the bonding members bond the tab line to the two solar cells by bonding the tab line to the bus bar electrode included in the first solar cell and bonding the tab line to the bus bar electrode included in the second solar cell, and
in at least one of the two solar cells, a bonding length in the longitudinal direction of the tab line along which the bus bar electrode and the tab line are bonded together is shorter than a length of the bonding member in the longitudinal direction of the tab line.

8. The solar cell module according to claim 1, wherein
the first solar cell includes a bus bar electrode and finger electrodes on the front surface and the second solar cell includes a bus bar electrode and finger electrodes on the back surface, the bus bar electrodes extending in a longitudinal direction of the tab line and being configured to transfer electric charges from received light to the tab line, the finger electrodes crossing the bus bar electrodes in a plan view and being configured to collect electric charges from received light,
the bonding members bond the tab line to the two solar cells by bonding the tab line to the bus bar electrode included in the first solar cell and bonding the tab line to the bus bar electrode included in the second solar cell, and
in at least one solar cell among the two solar cells, in the first edge area of the at least one solar cell in the longitudinal direction of the tab line, a shortest distance between an outermost finger electrode among the finger electrodes and an edge of the at least one solar cell is shorter than a distance between an end of the bus bar electrode and the edge of the at least one solar cell.

9. The solar cell module according to claim 7, wherein
in at least one of the two solar cells, a length of the bus bar electrode in the longitudinal direction of the tab line is shorter than a length of the bonding member in the longitudinal direction of the tab line.

10. The solar cell module according to claim 9, wherein
in each of the two solar cells, the bus bar electrode is included only in the central area among the first edge area and the central area,
the first solar cell further includes finger electrodes and a connection electrode on the front surface and the second solar cell further includes finger electrodes and a connection electrode on the back surface, the finger electrodes crossing the bus bar electrodes in a plan view and being configured to collect electric charges from received light, the connection electrodes each connecting, among the finger electrodes, a finger electrode in the first edge area to a finger electrode in the central area, and
in each of the two solar cells, the finger electrode in the central area connected by the connection electrode has a portion having a greatest width among widths of the finger electrodes.

11. The solar cell module according to claim 10, wherein
in each of the two solar cells,
at least two of the finger electrodes are included in the first edge area, and
a portion of the connection electrode closer to the central area has a width greater than a width of a portion of the connection electrode farther from the central area.

12. The solar cell module according to claim 10, wherein
in each of the two solar cells, the connection electrode has a portion covered with the tab line in a plan view.

13. The solar cell module according to claim 12, wherein
in each of the two solar cells, the connection electrode is discretely covered with the tab line in the plan view.

14. The solar cell module according to claim 12, wherein
in each of the two solar cells, the connection electrode has a portion separate from the bonding member in the first edge area.

15. The solar cell module according to claim 14, wherein
in each of the two solar cells, the connection electrode is discretely separate from the bonding member in the first edge area.

16. The solar cell module according to claim 10, wherein
the first solar cell further includes a dummy electrode on the front surface in the first edge area,
the second solar cell further includes a dummy electrode on the back surface in the first edge area, and
in each of the two solar cells, surface area occupancy in a plan view of the dummy electrode relative to the bonding member in the first edge area is lower than surface area occupancy in the plan view of the bus bar electrode relative to the bonding member in the central area.

17. The solar cell module according to claim 16, wherein
in each of the two solar cells, the dummy electrode is discretely disposed in the first edge area.

18. The solar cell module according to claim 10, wherein
the first solar cell further includes a support electrode on the front surface and the second solar cell further includes a support electrode on the back surface, the support electrodes supporting the tab line and each extending in an approximately extreme edge portion, in which the bonding member is not disposed, of the first edge area in a longitudinal direction of the tab line.

19. The solar cell module according to claim 18, wherein
in each of the two solar cells, the support electrode is electrically connected with the connection electrode.

20. The solar cell module according to claim 10, wherein
in the at least one of the two solar cells in which the length of the bus bar electrode is shorter than the length of the bonding member, the connection electrode is included in an inactive area of a flat area, the inactive area not having a light collecting function.

21. The solar cell module according to claim 1, wherein
the first solar cell further includes a bus bar electrode and finger electrodes on the front surface, and the second solar cell further includes a bus bar electrode and finger electrodes on the back surface, the bus bar electrodes extending in a longitudinal direction of the tab line and being configured to transfer electric charges from received light to the tab line, the finger electrodes crossing the bus bar electrodes in a plan view and being configured to collect electric charges from received light,
in each of the two solar cells, the bus bar electrode is included in at least a portion of an area other than the first edge area, and
in the plan view, on at least one of the front surface of the first solar cell and the back surface of the second solar cell, spacing between finger electrodes in a first area among the finger electrodes is greater than spacing between finger electrodes in a second area among the finger electrodes, the second area being closer to the bus bar electrode than the first area is.

22. The solar cell module according to claim 9, wherein
in each of the two solar cells, the bus bar electrode is in at least a portion of an area other than the first edge area,
the first solar cell further includes finger electrodes on the front surface, and the second solar cell further includes finger electrodes on the back surface, the finger electrodes crossing the bus bar electrodes in a plan view and being configured to collect electric charges from received light, and
on at least one of the front surface of the first solar cell and the back surface of the second solar cell, a distance between, among the finger electrodes, a finger electrode which crosses an endmost portion of the bus bar electrode in the first edge area and a finger electrode next to the finger electrode which crosses the endmost portion is longer in a first area than in a second area that is closer to the bus bar electrode than the first area is.

23. The solar cell module according to claim 1, wherein
on each of the front surface and a back surface of the first solar cell and on each of a front surface and the back surface of the second solar cell, the two solar cells each include:
a bus bar electrode which extends in a longitudinal direction of the tab line, and transfers electric charges from received light to the tab line; and
finger electrodes which cross the bus bar electrode in a plan view, and collect electric charges from received light, and
in each of the two solar cells, among the finger electrodes on the back surface, at least one finger electrode in the first edge area on the back surface is closer to an edge of the solar cell than an outermost finger electrode in the first edge area on the front surface is, among the finger electrodes on the front surface.

24. The solar cell module according to claim 1, wherein
on each of the front surface and a back surface of the first solar cell and on each of a front surface and the back surface of the second solar cell, the two solar cells each include:
a bus bar electrode which extends in a longitudinal direction of the tab line, and transfers electric charges from received light to the tab line; and
finger electrodes which cross the bus bar electrode in a plan view, and collect electric charges from received light, and
in each of the two solar cells, surface area occupancy of the bus bar electrode and the finger electrodes on the back surface is higher than surface area occupancy of the bus bar electrode and the finger electrodes on the front surface.
